(19) United States
(12) Patent Application Publication
(10) Pub. No.: US 2026/0247730 A1
(43) Pub. Date: Aug. 20, 2026

(54) IMAGE SENSOR INCLUDING DUAL VERTICAL TRANSFER GATE

(71) Applicant: Samsung Electronics Co., Ltd., Suwon-si (KR)

(72) Inventors: Youngwoo CHUNG, Suwon-si (KR); Jeongki KIM, Suwon-si (KR); Hyounmin BAEK, Suwon-si (KR); Sang Bae YU, Suwon-si (KR); Sojung KANG, Suwon-si (KR); Suhyuk YANG, Suwon-si (KR); Dongwook WON, Suwon-si (KR); Yujin LEE, Suwon-si (KR)

(73) Assignee: Samsung Electronics Co., Ltd., Suwon-si (KR)

(21) Appl. No.: 19/430,688

(22) Filed: Dec. 23, 2025

(30) Foreign Application Priority Data
Feb. 19, 2025 (KR) 10-2025-0021828

(51) Int. Cl. H10F 39/00; H10F 39/18

(52) U.S. Cl. CPC H10F 39/80373; H10F 39/182; H10F 39/802; H10F 39/807; H10F 39/811

(57) ABSTRACT

An image sensor including a substrate having a first surface and a second surface opposing the first surface; a first photoelectric conversion element (PD) region including a first PD in the substrate; a second PD region including a second PD in the substrate; a deep isolation pattern between the first PD and the second PD; a transfer gate in the first PD region and including a horizontal portion on the first surface of the substrate, a first vertical portion extending into the substrate, and a second vertical portion extending into the substrate; and a shallow isolation pattern. The first and second vertical portions are connected to the horizontal portion. The shallow isolation pattern vertically overlaps with the horizontal portion in a first direction perpendicular to the first surface of the substrate.

### CROSS-REFERENCE TO RELATED APPLICATION(S)

This U.S. non-provisional application claims priority under 35 USC § 119 to Korean Patent Application No. 10-2025-0021828, filed on Feb. 19, 2025, in the Korean Intellectual Property Office, the disclosure of which is herein incorporated by reference in its entirety.

### BACKGROUND

The present disclosure relates to image sensors and, more particularly, to image sensors including a dual vertical transfer gate.

An image sensor is a semiconductor device that converts an optical image into an electrical signal. Image sensors can be classified into a charge coupled device (CCD) type and a complementary metal oxide semiconductor (CMOS) type. The CMOS type image sensor is provided with a plurality of pixels arranged two-dimensionally. Each of the pixels may include a photodiode (PD) as a photoelectric conversion element. Each of the pixels may include a transfer transistor to transfer photocharges from the photodiode to a floating diffusion region (FD). To improve performance of the image sensor while reducing pixel size, the transfer transistor may include a dual transfer gate having two vertical portions.

### SUMMARY

Some objects of the present disclosure among others are directed to providing an image sensor with improved photocharge transfer efficiency.

Some example embodiments of the inventive concepts provide an image sensor that includes a substrate having a first surface and a second surface opposing the first surface; a first photoelectric conversion element (PD) region comprising a first PD in the substrate; a second PD region comprising a second PD in the substrate; a deep isolation pattern between the first PD and the second PD; a transfer gate in the first PD region and comprising a horizontal portion on the first surface of the substrate, a first vertical portion extending into the substrate, and a second vertical portion extending into the substrate; and a shallow isolation pattern, wherein the first and second vertical portions are connected to the horizontal portion, and wherein the shallow isolation pattern is vertically overlapping with the horizontal portion in a first direction perpendicular to the first surface of the substrate.

Some example embodiments of the inventive concepts provide an image sensor that includes a substrate having a first surface and a second surface opposing the first surface; a first photoelectric conversion element (PD) region comprising a first PD in the substrate; a second PD region comprising a second PD in the substrate; a deep isolation pattern between the first PD and the second PD; a transfer gate in the first PD region and comprising a horizontal portion on the first surface of the substrate, a first vertical portion extending into the substrate, and a second vertical portion extending into the substrate; and a shallow isolation pattern, wherein the first and second vertical portions are connected to the horizontal portion, wherein the shallow isolation pattern is between the first vertical portion and the second vertical portion in a plan view, and wherein an area of the horizontal portion in the plan view is greater than a combined area of the first vertical potion and the second vertical portion in the plan view.

Some example embodiments of the inventive concepts provide an image sensor that includes
a substrate having a first surface and a second surface opposing the first surface; a first photoelectric conversion element (PD) region comprising a first PD in the substrate; a second PD region comprising a second PD in the substrate; a third PD region comprising a third PD in the substrate; a fourth PD region comprising a fourth PD in the substrate; and a floating diffusion region vertically overlapping with the first to fourth PD regions in a plan view, wherein each of the first to fourth PD region comprising: a transfer gate comprising a horizontal portion on the first surface of the substrate, a first vertical portion extending into the substrate, and a second vertical portion extending into the substrate; and a shallow isolation pattern, wherein the first and second vertical portions are connected to the horizontal portion, wherein the shallow isolation pattern is between the first vertical portion and the second vertical portion in the plan view, and wherein an area of the horizontal portion in the plan view is greater than a combined area of the first vertical potion and the second vertical portion in the plan view.

### BRIEF DESCRIPTION OF DRAWINGS

FIG. 1 is a block diagram of an image sensor according to some example embodiments of the present disclosure.

FIG. 2 is a circuit diagram of a pixel array of an image sensor according to some example embodiments of the present disclosure.

FIG. 3 is a circuit diagram of a pixel array of an image sensor according to some example embodiments of the present disclosure.

FIG. 4 is a plan view showing an image sensor according to some example embodiments of the present disclosure.

FIG. 5 is an enlarged plan view showing a pixel region group of an image sensor according to some example embodiments of the present disclosure.

FIG. 6 is a cross-sectional view taken along line A-A′ of FIG. 5.

FIG. 7 is a cross-sectional view taken along line B-B′ of FIG. 5.

FIG. 8 is a cross-sectional view taken along line C-C′ of FIG. 5.

FIG. 9 is a cross-sectional view taken along line D-D′ of FIG. 5.

FIG. 10 is an enlarged plan view showing a pixel region group of an image sensor according to some example embodiments of the present disclosure.

FIG. 11 is a cross-sectional view taken along line B-B′ of FIG. 10.

FIG. 12 is a cross-sectional view taken along line D-D′ of FIG. 10.

FIG. 13 is a cross-sectional view showing an image sensor according to some example embodiments of the present disclosure.

FIGS. 14A, 15A, 16A, 17A, 18A, 19A and 20A are for explaining a method of manufacturing an image sensor according to some example embodiments of the present disclosure, which are cross-sectional views corresponding to line A-A′ of FIG. 5

FIGS. 14B, 15B, 16B, 17B, 18B, 19B and 20B are for explaining the method of manufacturing the image sensor according to some example embodiments of the present disclosure, which are cross-sectional views corresponding to line B-B′ of FIG. 5.

FIGS. 14C, 17C, 18C, 19C and 20C are for explaining the method of manufacturing the image sensor according to some example embodiments of the present disclosure, which are cross-sectional views corresponding to D-D′ of FIG. 5.

FIGS. 21 and 22 are cross-sectional views for explaining a method of manufacturing an image sensor according to some example embodiments of the present disclosure.

FIG. 23 is a plan view showing a pixel region group of an image sensor according to some example embodiments of the present disclosure.

FIGS. 24A and 24B are cross-sectional views taken along line A-A′ and line B-B′ of FIG. 23.

FIGS. 25 and 27 are plan views showing a method of manufacturing an image sensor according to some example embodiments of the present disclosure.

FIGS. 26A, 26B, 28A and 28B are cross-sectional views taken along line A-A′ and line B-B′ of FIGS. 25 and 27, respectively.

### DETAILED DESCRIPTION

Hereafter, some example embodiments of the present disclosure will be clearly and thoroughly described with reference to the accompanying drawings.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

Also, for example, “at least one of A, B, and C” and similar language (e.g., “at least one selected from the group consisting of A, B, and C”) may be construed as A only, B only, C only, or any combination of two or more of A, B, and C, such as, for instance, ABC, AB, BC, and AC.

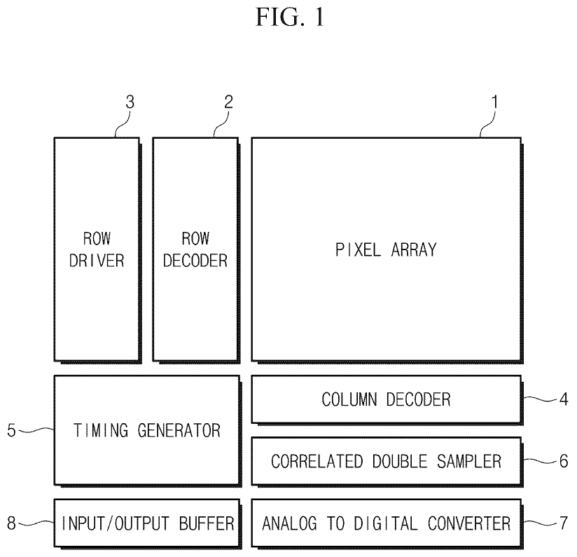

FIG. 1 is a block diagram of an image sensor according to some example embodiments of the present disclosure.

Referring to FIG. 1, the image sensor according to some example embodiments of the present disclosure may include a pixel array 1, a row decoder 2, a row driver 3, a column decoder 4, a timing generator 5, a correlated double sampler (CDS) 6, an analog to digital converter (ADC) 7, and an input/output buffer (I/O buffer) 8.

The pixel array 1 may include pixels arranged two-dimensionally, and the pixels may convert optical signals into electrical signals. The pixel array 1 may be driven by driving signals (e.g., a pixel selection signal, a reset signal, and/or a charge transfer signal) transmitted from the row driver 3. The converted electrical signals may be provided to the CDS 6.

The row driver 3 may provide the driving signals for driving the pixels based on decoded results from the row decoder 2 to the pixel array 1. When the pixels are arranged in a matrix form, the driving signals may be provided in a row unit.

The timing generator 5 may provide a timing signal and a control signal to the row decoder 2 and the column decoder 4.

The CDS 6 may receive the electrical signals generated from the pixel array 1 and may hold and sample the received signals. The CDS 6 may double-sample a specific noise level and a signal level caused by an electrical signal to output a difference level corresponding to the difference between the noise level and the signal level.

The ADC 7 may convert an analog signal corresponding to the difference level output from the CDS 6 into a digital signal and may output the digital signal.

The I/O buffer 8 may latch the digital signals and sequentially output the latched signals to an image signal processor (not shown) based on the decoded results from the column decoder 4.

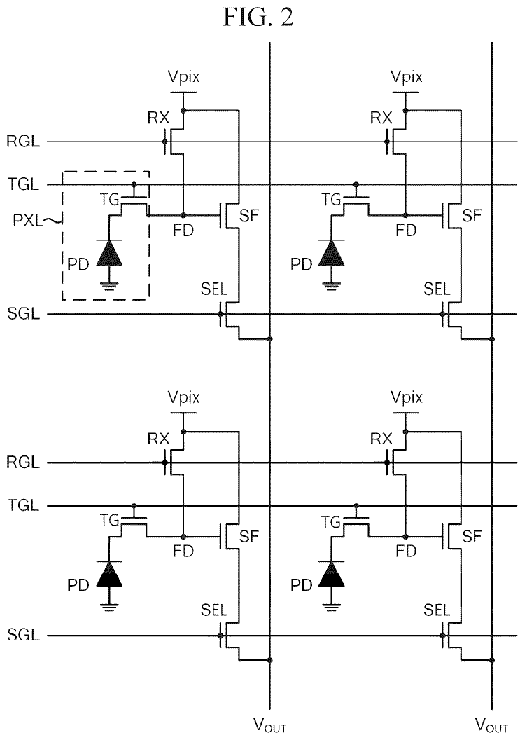

FIG. 2 is a circuit diagram of a pixel array of an image sensor according to some example embodiments of the present disclosure.

Referring to FIG. 2, the pixel array may include pixels PXL, and the pixels PXL may be arranged in a matrix form. Each of the pixels PXL may include pixel transistors and a transfer transistor gate TG. And each of the pixels PXL may be connected to corresponding logic transistors or a plurality of pixels PXL may share logic transistors and a floating diffusion region FD. The logic transistors may include a reset transistor RX, a selection transistor SEL, and a source follower transistor SF.

The photoelectric conversion element PD may generate and accumulate photocharges in proportion to an amount of light incident from the outside. The photoelectric conversion element PD may include a photodiode, a phototransistor, a photogate, a pinned photodiode, or a combination thereof. The transfer transistor gate TG may transfer the photocharges generated from the photoelectric conversion element PD to the floating diffusion region FD. A transfer transistor gate TG may be connected to a transfer gate line TGL. The floating diffusion region FD may receive and cumulatively store the photocharges generated from the photoelectric conversion element PD.

A gate of the source follower transistor SF may be connected to the floating diffusion region FD. A drain terminal of the source follower transistor SF may be connected to a power supply terminal Vₚᵢₓ that may receive a power supply voltage. The source follower transistor SF may be controlled according to an amount of the photocharges accumulated in the floating diffusion region FD.

The reset transistor RX may periodically reset the charges accumulated in the floating diffusion region FD. A gate of the reset transistor RX may be connected to a reset gate line RGL. A source terminal of the reset transistor RX may be connected to the floating diffusion region FD, and a drain terminal of the reset transistor RX may be connected to the power supply terminal Vₚᵢₓ. When the reset transistor RX is turned on, the power supply voltage of the power supply terminal Vₚᵢₓ may be applied to the floating diffusion region FD through the reset transistor RX. For example, when the reset transistor RX is turned on, the charges accumulated in the floating diffusion region FD may be discharged by the power supply voltage, thereby resetting the floating diffusion region FD.

The source follower transistor SF may serve as a source follower buffer amplifier. The source follower transistor SF may amplify a potential change in floating diffusion region FD and output the amplified potential change to an output line V_{OUT}.

A gate of the selection transistor SEL may be connected to a selection gate line SGL. A drain terminal of the selection transistor SEL may be connected to a source terminal of the source follower transistor SF, and a source terminal of the selection transistor SEL may be connected to the output line V_{OUT}. The selection transistors SEL of the pixels PXL to be read in a row unit may be selected by a selection signal applied through the corresponding selection gate line SGL. When the selection transistor SEL is turned on, the potential change amplified by the source follower transistor SF may be output to the output line V_{OUT} through the selection transistor SEL.

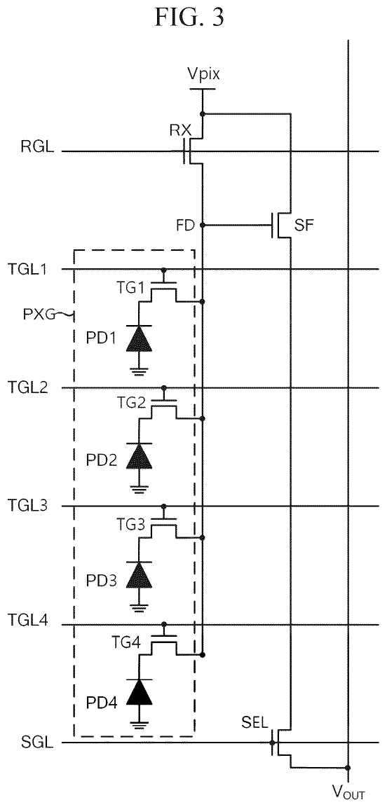

FIG. 3 is a circuit diagram of a pixel array of an image sensor according to some example embodiments of the present disclosure.

Referring to FIG. 3, the pixel array may include pixel groups PXG, and each of the pixel groups PXG may include pixels. A circuit diagram of one pixel group PXG is shown in FIG. 3.

In some example embodiments, the pixel group PXG may include four pixels (e.g., first to fourth pixels). The first pixel may include a first transfer transistor gate TG1 and a first photoelectric conversion element PD1, the second pixel may include a second transfer transistor gate TG2 and a second photoelectric conversion element PD2, the third pixel may include a third transfer transistor gate TG3 and a third photoelectric conversion element PD3, and the fourth pixel may include a fourth transfer transistor gate TG4 and a fourth photoelectric conversion element PD4. Each of the first to fourth transfer transistor gates TG1 to TG4 may be connected to first to fourth transfer gate lines TGL1 to TGL4, respectively. In some example embodiments, the first to fourth pixels of the pixel group PXG may share the reset transistor RX, the source follower transistor SF, and the selection transistor SEL described above.

In some example embodiments of FIG. 3, the pixel group PXG may include four pixels. However, some example embodiments of the present disclosure are not limited thereto, and the number of pixels in the pixel group PXG may be variously changed.

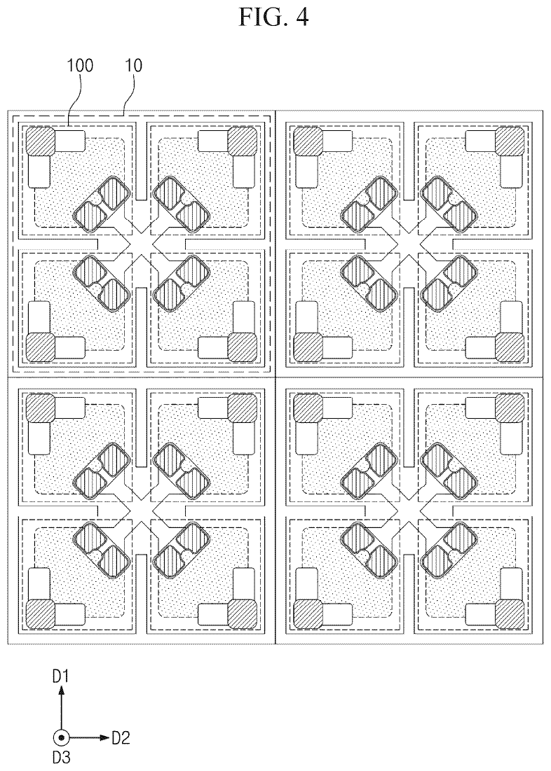

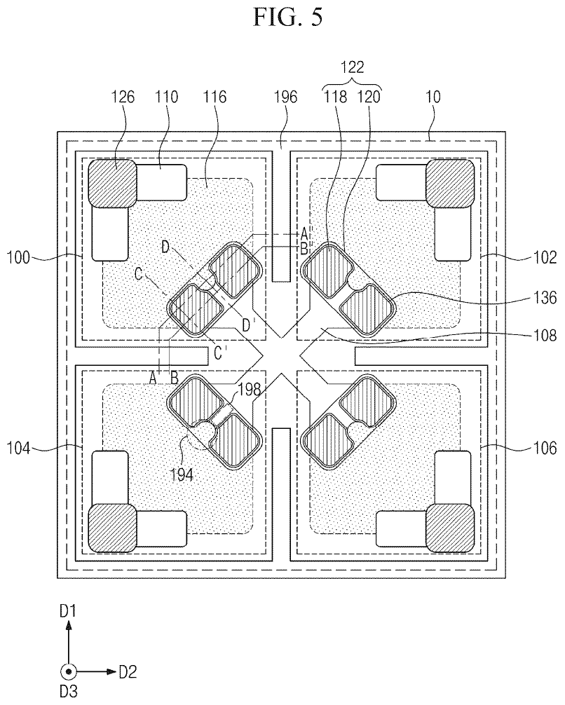

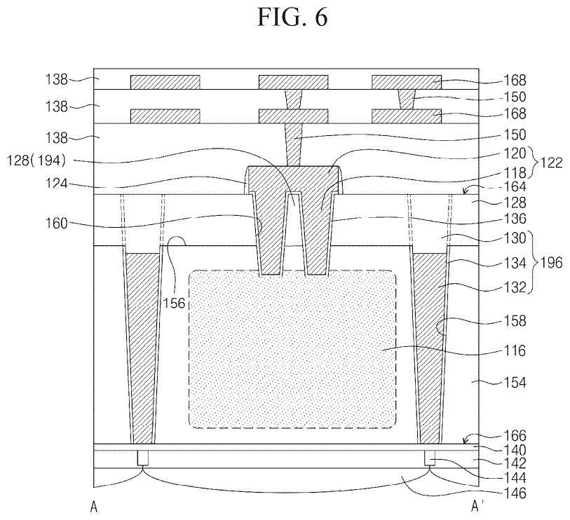

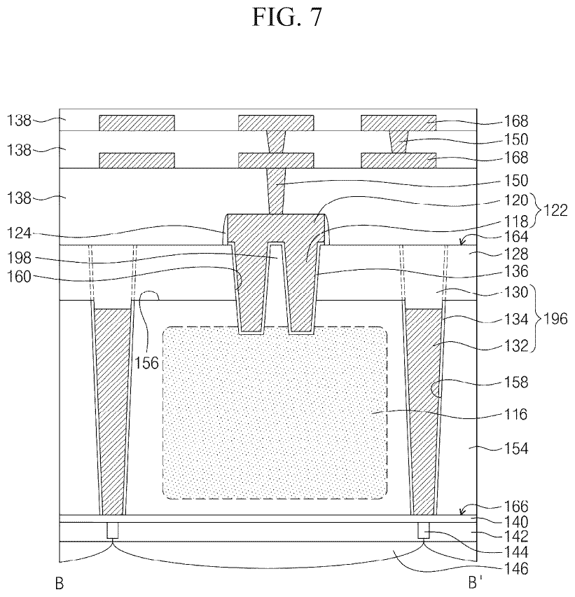

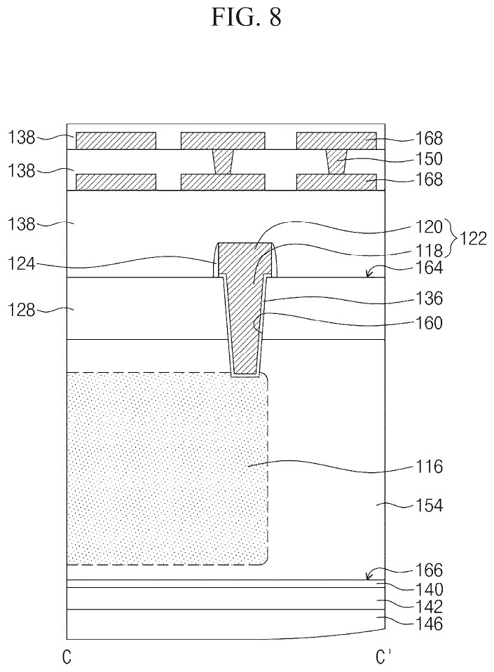

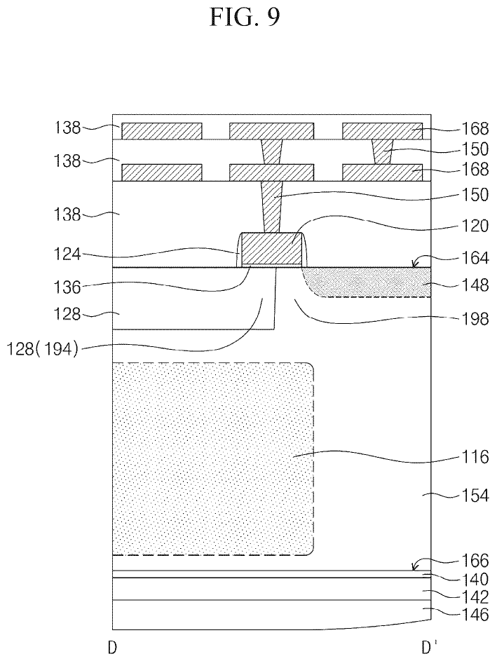

FIG. 4 is a plan view showing an image sensor according to some example embodiments of the present disclosure. FIG. 5 is an enlarged plan view showing a pixel region group of an image sensor according to some example embodiments of the present disclosure. FIG. 6 is a cross-sectional view taken along line A-A′ of FIG. 5. FIG. 7 is a cross-sectional view taken along line B-B′ of FIG. 5. FIG. 8 is a cross-sectional view taken along line C-C′ of FIG. 5. FIG. 9 is a cross-sectional view taken along line D-D′ of FIG. 5.

Referring to FIGS. 4 to 9, the image sensor according to some example embodiments of the present disclosure may include a substrate 154. The substrate 154 may have a first surface 164 and a second surface 166 that are opposite to each other. In some example embodiments, the first surface 164 may be a front surface of the substrate 154, and the second surface 166 may be a back surface of the substrate 154. Light may be incident on the second surface 166. Accordingly, the second surface 166 may be a light incident surface.

The substrate 154 may be a semiconductor substrate. The substrate 154 may be, for example, a silicon substrate, a germanium substrate, or a silicon-germanium substrate. The substrate 154 may be doped with impurities of a first conductivity type. Accordingly, the substrate 154 may have the first conductivity type. For example, the impurities of the first conductivity type may be group III element. For example, the impurities of the first conductivity type may include p-type impurities such as boron B, aluminum Al, indium In, and/or gallium Ga.

A deep PD isolation pattern 196 may be formed in the substrate 154 to define photoelectric conversion element (PD) regions 100, 102, 104, and 106. In other words, the deep PD isolation pattern 196 may be formed in the substrate 154 to define a first photoelectric conversion element (PD) region 100, a second photoelectric conversion element (PD) region 102, a third photoelectric conversion element (PD) region 104, and a fourth photoelectric conversion element (PD) region 106. The deep PD isolation pattern 196 may be referred to as the deep isolation pattern in this specification. The deep isolation pattern is in contact with the first and second surfaces of the substrate 154. For example, each of the first to fourth photoelectric conversion element (PD) regions 100, 102, 104, and 106 may be a portion of the substrate 154 surrounded by the deep PD isolation pattern 196 in a plan view. In some example embodiments, the first to fourth photoelectric conversion element (PD) regions 100, 102, 104, and 106 adjacent to each other may form a photoelectric conversion element region group 10. Photoelectric conversion element region groups 10 may be defined in the substrate 154. The photoelectric conversion element region groups 10 may be arranged two-dimensionally in a matrix form.

Portions of the deep PD isolation pattern 196 between the first to fourth photoelectric conversion element (PD) regions 100, 102, 104, and 106 in each of the photoelectric conversion element region groups 10 may be spaced apart from each other. Therefore, the first to fourth photoelectric conversion element (PD) regions 100, 102, 104, and 106 in each of the pixel region groups may extend and be connected to each other. In some example embodiments, as shown in FIG. 5, each of the photoelectric conversion element region groups 10 may include the first to fourth photoelectric conversion element (PD) regions 100, 102, 104, and 106 arranged in the form of a 2×2 matrix. However, some example embodiments of the present disclosure are not limited thereto. The number of photoelectric conversion element (PD) regions in the photoelectric conversion element region group 10 may be variously changed. For example, the photoelectric conversion element region group 10 may include the photoelectric conversion element (PD) regions arranged in the form of a 2×4 matrix, a 4×4 matrix, or a 4×8 matrix. Hereinafter, for convenience of explanation, the embodiment of FIG. 5 may be described as an example.

As shown in FIG. 5, each of the photoelectric conversion element region groups 10 may include a first photoelectric conversion element (PD) region 100, a second photoelectric conversion element (PD) region 102, a third photoelectric conversion element (PD) region 104, and a fourth photoelectric conversion element (PD) region 106. The first photoelectric conversion element (PD) region 100 may be adjacent to the third photoelectric conversion element (PD) region 104 in an X-axis direction D1. The second photoelectric conversion element (PD) region 102 may be adjacent to the first photoelectric conversion element (PD) region 100 in a Y-axis direction D2 and may neighbor the fourth photoelectric conversion element (PD) region 106 in the X-axis direction D1. The fourth photoelectric conversion element (PD) region 106 may be adjacent to the third photoelectric conversion element (PD) region 104 in the Y-axis direction D2. The X-axis direction D1 and the Y-axis direction D2 may be parallel to the first surface 164 of the substrate 154 and may intersect each other.

The deep PD isolation pattern 196 may be provided in a deep trench 158 formed in the substrate 154. The deep trench 158 may be recessed from the first surface 164 or the second surface 166 of the substrate 154. In some example embodiments, the deep PD isolation pattern 196 may pass through the substrate 154.

In some example embodiments, as shown in FIG. 6, the deep PD isolation pattern 196 may include an insulating liner 134, a buried pattern 132, and a capping insulating pattern 130. The insulating liner 134 may conformally cover an inner surface of the deep trench 158. The insulating liner 134 may be provided between the substrate 154 and the buried pattern 132 to electrically insulate the substrate 154 from the buried pattern 132. The insulating liner 134 may be provided between the capping insulating pattern 130 and a shallow isolation pattern 128.

The insulating liner 134 may include an insulating material, for example, a silicon-based insulating material (e.g., silicon nitride (Si₃N₄), silicon oxide (SiO₂), silicon oxynitride, and/or silicon carbonitride (SiCN)) and/or a high-k metal oxide (e.g., hafnium oxide (HfOx), zirconium oxide (ZrO₂), and/or aluminum oxide (Al₂O₃)).

The insulating liner 134 is shown as a single layer in FIG. 6, but the present disclosure is not limited thereto. In some example embodiments, the insulating liner 134 may include stacked layers, and the stacked layers may include different materials.

The buried pattern 132 may be formed of a conductive material (e.g., doped polysilicon or a metal). The doped polysilicon may be doped with impurities of the first conductivity type (e.g., p-type) or impurities of a second conductivity type (e.g., n-type). For example, the buried pattern 132 may include polysilicon doped with boron (B), or polysilicon doped with phosphorus (P) or arsenic (As).

When the buried pattern 132 includes a metal, the buried pattern 132 may include at least one of copper, tungsten, aluminum, titanium, an organic or inorganic conductive material doped with an impurity, a conductive metal oxide, or a conductive polymer. The conductive metal oxide may be indium tin oxide (ITO), indium zinc oxide (IZO), aluminum-doped zinc oxide (AZO), indium gallium zinc oxide (IGZO), fluorine-doped tin oxide, and/or niobium (Nb)-doped anatase (TiO₂). But in some example embodiments, the buried pattern 132 may be formed of an insulating material.

The capping insulating pattern 130 may cover an upper end of the buried pattern 132 and may be adjacent to the first surface 164 of the substrate 154. The capping insulating pattern 130 may include an insulating material, for example, a silicon-based insulating material (e.g., silicon nitride (Si₃O₄), silicon oxide (SiO₂), silicon oxynitride, and/or silicon carbonitride (SiCN)) and/or a high-k metal oxide (e.g., hafnium oxide (HfOx), zirconium oxide (ZrO₂), and/or aluminum oxide (Al₂O₃)).

Some example embodiments of the present disclosure are not limited to the deep PD isolation pattern 196 described above. According to some example embodiments, the deep PD isolation pattern 196 may include the insulating liner 134 and an insulating pattern provided on the insulating liner 134 to fill the deep trench 158. For example, the buried conductive pattern may be omitted. For example, the insulating pattern may include an air gap.

The shallow isolation pattern 128 may be formed in the substrate 154 to define active regions. The shallow isolation pattern 128 may fill a shallow trench 156 recessed into the substrate 154 from the first surface 164 of the substrate 154. For example, the substrate 154 may define shallow trench 156 recessed from the first surface 164 of the substrate 154. Therefore, the shallow isolation pattern 128 may be disposed adjacent to the first surface 164 of the substrate 154. The shallow isolation pattern 128 may be exposed on the first surface 164.

In some example embodiments, as shown in FIG. 6, the deep PD isolation pattern 196 may pass through the shallow isolation pattern 128. For example, when the shallow isolation pattern 128, the insulating liner 134, and the capping insulating pattern 130 are formed of the same insulating material, interfaces between them may not be visible.

In some example embodiments, as shown in FIG. 5, the shallow isolation pattern 128 may define a first active region 108 (which may be referred to as an active region in the present specification) and a second active region 110 in each of the first to fourth photoelectric conversion element (PD) regions 100, 102, 104, and 106. In some example embodiments, the first active regions 108 in each of the photoelectric conversion element region groups 10 may extend and be connected to each other at a central portion of the photoelectric conversion element region group 10.

Each of the first and second active regions 108 and 110 may be a portion of the substrate 154 surrounded by the shallow isolation pattern 128. The first active region 108 may include a channel portion 198 and other portions.

The shallow isolation pattern 128 may include at least one of various insulating materials. For example, the shallow isolation pattern 128 may include at least one of a silicon oxide layer, a silicon nitride layer, and a silicon oxynitride layer.

A photoelectric conversion element (PD) 116 may be provided in each of the first to fourth photoelectric conversion element (PD) regions 100, 102, 104, and 106. In this specification, the photoelectric conversion element (PD) comprised in the first photoelectric conversion element (PD) region 100 may be referred to as a first PD, the photoelectric conversion element (PD) comprised in the second photoelectric conversion element (PD) region 102 may be referred to as a second PD, the photoelectric conversion element (PD) comprised in the third photoelectric conversion element (PD) region 104 may be referred to as a third PD, and the photoelectric conversion element (PD) comprised in the fourth photoelectric conversion element (PD) region 106 may be referred to as a fourth PD. The deep PD isolation pattern 196 may be disposed between the first PD and the second PD. The photoelectric conversion element (PD) 116 may be interposed between the first surface 164 and the second surface 166 of the substrate 154. The photoelectric conversion element (PD) 116 may be a region doped with impurities of the second conductivity type. The second conductivity type may be a conductivity type opposite to the first conductivity type. In some example embodiments, the impurities of the second conductivity type may include group V element. For example, the impurities of the second conductivity type may include n-type impurities such as phosphorus and/or arsenic. The photoelectric conversion element (PD) 116 having the second conductivity type may be PN-junctioned with each of the first to fourth photoelectric conversion element (PD) regions 100, 102, 104, and 106 having the first conductivity type to form a photoelectric conversion element (e.g., a photodiode). The photoelectric conversion elements formed in each of the photoelectric conversion element region groups 10 may each correspond to the first to fourth photoelectric conversion elements PD1, PD2, PD3, and PD4 in FIG. 3.

A transfer transistor gate (TG) 122 may be disposed on the first active region 108 in each of the first to fourth photoelectric conversion element (PD) regions 100, 102, 104, and 106. For clarity, the transfer transistor gate (TG) 122 is referred to as the transfer gate throughout this specification. The transfer transistor gate (TG) 122 may be disposed on the first surface 164 of the substrate 154. A gate insulating layer 136 may be disposed between the transfer transistor gate (TG) 122 and the first active region 108. A gate spacer 124 may be provided on side surfaces of the transfer transistor gate (TG) 122. For example, the gate insulating layer 136 may include at least one of silicon oxide, silicon oxynitride, or a high-k material. The gate spacer 124 may include at least one of silicon oxide, silicon nitride, or silicon oxynitride.

In some example embodiments, the transfer transistor gate (TG) 122 may include a pair of vertical portions 118 each filling a pair of gate trenches 160 recessed from an upper surface of the first active region 108 and a horizontal portion 120 connected to the pair of vertical portions 118. In this specification, one of the pair of vertical portions may be referred to as a first vertical portion, and the other may be referred to as a second vertical portion. For example, the transfer transistor gate (TG) 122 in the first photoelectric conversion element (PD) region 100, may comprise the horizontal portion 120 on the first surface of the substrate 154, the first vertical portion extending into the substrate 154, and the second vertical portion extending into the substrate 154. The first and second vertical portions may be connected to the horizontal portion 120. The shallow isolation pattern 128 may be vertically overlap with the horizontal portion 120 in a first direction perpendicular to the first surface of the substrate 154. An area of the horizontal portion in the plan view is greater than a combined area of the first vertical portion and the second vertical portion in the plan view. For example, the substrate 154 may define the pair of gate trenches 160 in the active region 106. For example, the gate insulating layer 136 may extend and be disposed between the pair of vertical portions 118 and inner surfaces of the pair of gate trenches 160. The pair of vertical portions 118 may be electrically connected to each other by the horizontal portion 120 connected to the pair of vertical portions 118. In FIG. 5, hatching of the horizontal portion 120 is omitted to show the pair of vertical portions 118 and the horizontal portion 120. A transfer transistor including the transfer transistor gate (TG) 122 including the pair of vertical portions 118 may be a dual vertical channel transistor. Upper surfaces of the active regions 108 and 110 may be portions of the first surface 164 of the substrate 154.

As shown in FIG. 6, in some example embodiments, the pair of gate trenches 160 may extend from the first surface 164 to the photoelectric conversion region 116. For example, bottom portions of the pair of gate trenches 160 may be surrounded by the photoelectric conversion element (PD) 116. However, some example embodiments of the present disclosure are not limited thereto. In some example embodiments, the pair of gate trenches 160 may extend vertically from the first surface 164 and may be spaced apart from the photoelectric conversion element (PD) 116.

Each of the first and second vertical portions may comprise an upper surface and a lower surface opposing the upper surface. A distance from the lower surface of the first vertical portion to the lower surface of the second vertical portion in a second direction perpendicular to the first direction in a first vertical view may be greater than a distance from the upper surface of the first vertical portion to the upper surface of the second vertical portion in the second direction in the first vertical view.

The pair of gate trenches 160 may be symmetrically disposed with respect to each other. Alternatively, in some example embodiments, the pair of gate trenches 160 may be asymmetrically disposed with respect to each other.

According to some example embodiments, as shown in FIGS. 5 and 6, the shallow isolation pattern 128 may include an extension 194 (which may be referred to as an overlapping portion in the present specification) extending between the pair of vertical portions 118 of the transfer gate 122. The extension 194 of the shallow isolation pattern 128 and the channel portion 198 of the first active region 108 may be provided between the pair of vertical portions 118. The horizontal portion 120 of the transfer gate 122 may cover the extension 194 of the shallow isolation pattern 128 and the channel portion 198 of the first active region 108. For example, an area overlapping with the horizontal portion 120 and the shallow isolation pattern 128 in the first direction is more than 60% less than the area of the horizontal portion 120 in the plan view. For example, a center of the horizontal portion in a first vertical view is offset from a center of a first vertical portion in the first vertical view. Both side surfaces of the extension 194 of the shallow isolation pattern 128 may each be adjacent to the pair of vertical portions 118 and the both side surfaces may be in contact with the gate insulating layer 136. A floating diffusion region 148 may be provided in the first active region 108 at one side of the transfer transistor gate (TG) 122. For example, the floating diffusion region 148 may be provided in the other portion of the first active region 108 provided at one side of the transfer transistor gate (TG) 122. The floating diffusion regions 148 in each of the photoelectric conversion element region groups 10 may extend and be connected to each other in a connected portion of the first active regions 108 of the photoelectric conversion element region group 10. In other hands, the floating diffusion region 148 is vertically overlapping with each of the first to fourth photoelectric conversion element (PD) regions 100, 102, 104, 106 in a plan view. The floating diffusion region 148 may be a region doped with impurities. The floating diffusion region 148 may be doped with impurities of the second conductivity type. When light is incident into the photoelectric conversion element (PD) 116, photocharges may be generated and accumulated in the photoelectric conversion element (PD) 116. When the transfer transistor including the transfer transistor gate (TG) 122 is turned on, the accumulated photocharges may be transferred to the floating diffusion region 148 through the transfer transistor.

In some example embodiments, the first photoelectric conversion element (PD) region 100 may further comprise the floating diffusion regions 148. The first vertical portion may be disposed between the shallow isolation pattern and the floating diffusion region in a second vertical view different from the first vertical view. In some example embodiments, a height of the floating diffusion region 148 from the first surface of the substrate 154 in the first direction in the second vertical view may be less than a height of the shallow isolation pattern from the first surface of the substrate 154 in the first direction in the second vertical view. A height of the first vertical portion from the first surface of the substrate 154 in the first direction in the second vertical view is different from the height of the shallow isolation pattern 128 from the first surface of the substrate 154 in the first direction in the second vertical view. The height of the first vertical portion from the first surface of the substrate in the first direction in the second vertical view is smaller than the height of the shallow isolation pattern from the first surface of the substrate in the first direction in the second vertical view.

According to the above-described embodiments, the extension 194 may be disposed between the pair of vertical portions 118 of the transfer transistor gate (TG) 122 and may be vertically overlapping with the horizontal portion 120 of the transfer transistor gate (TG) 122. Therefore, the volume of the channel portion 198 below the horizontal portion 120 may be reduced. As a result, a travel path of the photocharges between the photoelectric conversion element (PD) 116 and the floating diffusion region 148 may be reduced. The travel path of the photocharges may include a vertical travel path along a side surface of the vertical portions 118 and a horizontal travel path along a lower surface of the horizontal portion 120. Since the volume of the channel portion 198 is reduced due to the extension 194 of the shallow isolation pattern 128, the vertical and horizontal travel paths of the photocharges may be reduced. Consequently, the travel path of the photocharges may be reduced, thereby improving photocharge transfer efficiency of the image sensor.

Logic transistors may each be formed in at least some of the second active regions 110 of the first to fourth photoelectric conversion element (PD) regions 100, 102, 104, and 106 in each of the photoelectric conversion element region groups 10. In some example embodiments, the logic transistors may include the reset transistor RX, the source follower transistor SF, and the selection transistor SEL that are described in FIG. 3.

For example, a gate electrode 126 may be provided on the second active region 110 of each of the first to fourth photoelectric conversion element (PD) regions 100, 102, 104, and 106, and the gate insulating layer 136 may be disposed between the gate electrode 126 and the second active region 110. The gate spacer 124 may also be provided on side surfaces of the gate electrode 126. Source/drain regions may each be provided in the second active region 110 at both sides of the gate electrode 126. The gate electrode 126 and the source/drain regions may constitute a transistor. The transistors formed in the second active regions 110 of the first, second, third, and fourth photoelectric conversion element (PD) regions 100, 102, 104, and 106 may be referred to as first, second, third, and fourth transistors, respectively. Three of the first to fourth transistors may be the reset transistor RX, the source follower transistor SF, and the selection transistor SEL. The remaining one of the first to fourth transistors may be a dummy transistor. Alternatively, the remaining one of the first to fourth transistors may be a conversion gain transistor. Although not shown, the conversion gain transistor may be connected in series between the reset transistor RX and the floating diffusion region FD in FIG. 3. For example, the logic transistors may include the reset transistor RX, the source follower transistor SF, the selection transistor SEL, and the conversion gain transistor.

First interlayer insulating layers 138 may be stacked on the first surface 164 of the substrate 154, and first wirings 168 and first contact plugs 150 may be disposed in the first interlayer insulating layers 138. To implement the pixel group PXG of FIG. 3, the first wirings 168 and the first contact plugs 150 may be suitably connected to the gate electrodes 126, the source/drain regions in the second active regions 110, the transfer gates 122, and the floating diffusion region 148.

A light transmission layer 140 may be provided on the second surface 166 of the substrate 154 to cover the second surface 166. The light transmission layer 140 may cover lower surfaces of the deep PD isolation pattern 196. However, some example embodiments of the present disclosure are not limited thereto. In some example embodiments, the light transmission layer 140 may also extend onto an inner surface of the deep trench 158. For example, the deep trench 158 may extend from the second surface 166 of the substrate 154 toward the shallow isolation pattern 128, and the deep PD isolation pattern 196 may include the light transmission layer 140 in the deep trench 158. For example, the capping insulating pattern 130 and the buried pattern 132 may be omitted.

The light transmission layer 140 may be formed of a transparent insulating material. For example, the light transmission layer 140 may include a silicon-based insulating material (e.g., silicon oxide, silicon nitride, and/or silicon oxynitride) and/or a high-k material (e.g., hafnium oxide and/or aluminum oxide). The light transmission layer 140 may have a single-layer structure or a multi-layer structure. In some example embodiments, the light transmission layer 140 may perform a function as an antireflective layer and/or a function as a fixed charge layer. In some example embodiments, when the light transmission layer 140 is used as the antireflective layer, the light transmission layer 140 may include, for example, at least one of hafnium oxide (HfOx), zirconium oxide (ZrO₂), and aluminum oxide (Al₂O₃). For example, the light transmission layer 140 may limit and/or prevent reflection of light so that light incident on the second surface 166 of the substrate 154 may smoothly reach the photoelectric conversion element (PD) 116. In some example embodiments, when the light transmission layer 140 is used as the fixed charge layer, the light transmission layer 140 may have negative fixed charges. For example, the light transmission layer 140 may include a metal oxide or a metal fluoride containing at least one of hafnium, zirconium, tantalum, yttrium, or a lanthanoid. In some example embodiments, the light transmission layer 140 may include the fixed charge layer and the antireflective layer that are sequentially stacked.

A grid structure 144 may be provided on the light transmission layer 140, and color filters 142 may each be provided in openings defined by the grid structure 144. Microlenses 146 may be disposed on the color filters 142. The color filters 142 may be disposed between the light transmission layer 140 and the microlenses 146.

According to some example embodiments, as shown in FIG. 6, each of the color filters 142 may respectively vertically overlap each of the first to fourth photoelectric conversion element (PD) regions 100, 102, 104, and 106. Alternatively, each of the color filters 142 may vertically overlap photoelectric conversion element (PD) regions (e.g., the first to fourth photoelectric conversion element (PD) regions 100, 102, 104, and 106 of each of the photoelectric conversion element region groups 10). The color filters 142 may form a color filter array. Each of the color filters 142 may have one of red, green, and blue colors. Alternatively, each of the color filters 142 may have one of cyan, magenta, and yellow colors.

The grid structure 144 may be disposed between two adjacent color filters 142. The color filters 142 may be physically and optically separated from each other by the grid structure 144. Therefore, the grid structure 144 may guide incident light into the photoelectric conversion element (PD) 116.

The grid structure 144 may include a metal (e.g., titanium), a metal nitride (e.g., titanium nitride), and/or a low refractive material. The low refractive material may have insulating properties. The low refractive material may include a polymer and silica nanoparticles in the polymer.

In some example embodiments, the grid structure 144 may vertically overlap the deep PD isolation pattern 196. However, the present inventive concepts are not limited thereto. In some example embodiments, the grid structure 144 may have a structure that is laterally offset from the deep PD isolation pattern 196. The offset structure may be intentionally selected to optimize optical paths considering a margin in a manufacturing process and/or a traveling angle of incident light.

At least a portion of each of the microlenses 146 may be disposed to vertically overlap the corresponding photoelectric conversion element (PD) 116. Each of the microlenses 146 may be provided to condense the incident light and may include a spherical lens, an aspherical lens, or a combination thereof. The microlenses 146 may form a microlens array. In some example embodiments, the microlenses 146 may each be provided at positions corresponding to the photoelectric conversion elements (PD) 116 of the substrate 154. However, some example embodiments of the present application are not limited thereto. In some example embodiments, each of the microlenses 146 may have a structure that is laterally offset at a position corresponding to each of the photoelectric conversion elements (PD) regions 100, 102, 104, and 106. The offset structure may be intentionally selected to optimize optical paths considering a margin in a manufacturing process of the microlens 146 and/or a traveling angle of incident light. For example, the above-described grid structure 144, the color filters 142, and the microlenses 146 may have the offset structure.

The microlens 146 may be transparent to transmit light. The microlens 146 may include an organic material such as a polymer. For example, the microlens 146 may include a photoresist material or a thermosetting resin.

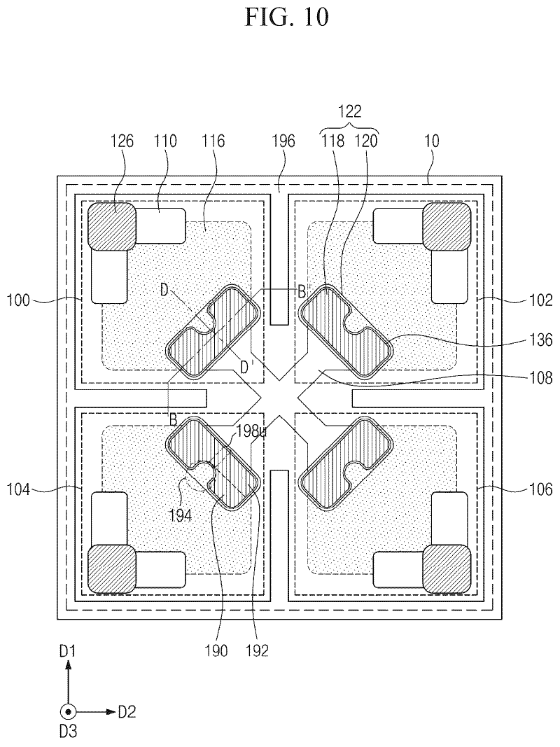

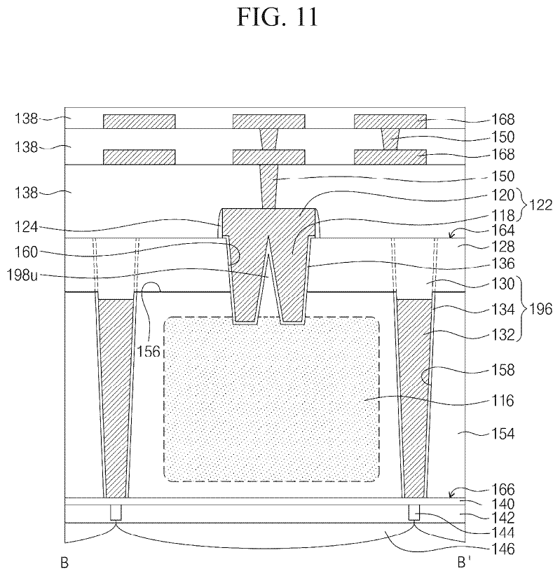

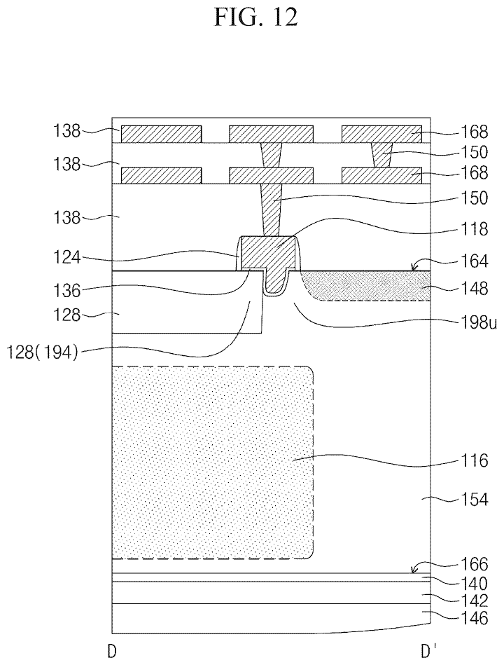

FIG. 10 is an enlarged plan view showing a pixel region group of an image sensor according to some example embodiments of the present disclosure. FIG. 11 is a cross-sectional view taken along line B-B′ of FIG. 10. FIG. 12 is a cross-sectional view taken along line D-D′ of FIG. 10.

Referring to FIGS. 10 to 12, in some example embodiments, each of a pair of vertical portions 118 may include a first portion 190 adjacent to an extension 194 of a shallow isolation pattern 128, and a second portion 192 adjacent to a channel portion 198u. Upper portions of the second portions 192 of the pair of vertical portions 118 may be in contact with each other, and lower portions of the second portions 192 of the pair of vertical portions 118 may be spaced apart from each other. In other hands, the upper portions of the first and second vertical portions are in contact with each other. For example, the channel portion 198u may be provided between the lower portions of the second portions 192 of the pair of vertical portions 118. The contacted portion of the second portions 192 of the pair of vertical portions 118 may be adjacent to one side surface of the extension 194 of the shallow isolation pattern 128.

According to some example embodiments of the present embodiments, a travel path of photocharges may be reduced due to the extension 194 of the shallow isolation pattern 128 and the contacted portion of the second portions 192 of the pair of vertical portions 118. Accordingly, a photocharge transfer efficiency of the image sensor may be improved.

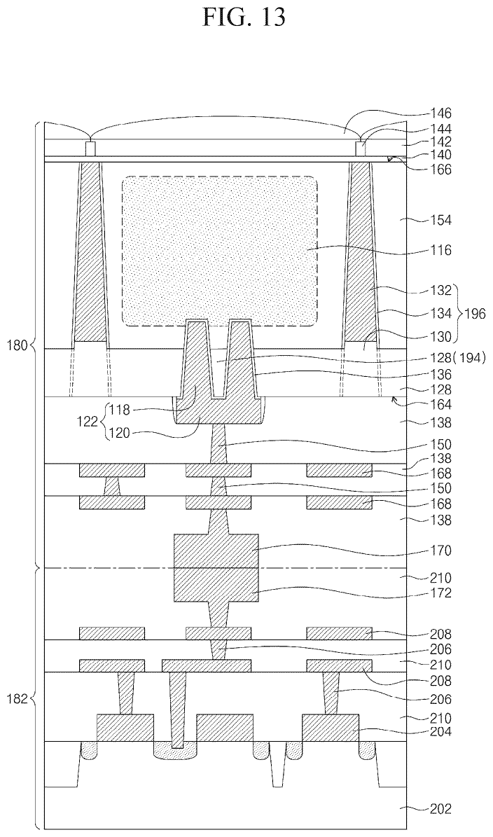

FIG. 13 is a cross-sectional view showing an image sensor according to some example embodiments of the present disclosure.

Referring to FIG. 13, according to some example embodiments, the image sensor may include a first structure 180 and a second structure 182. The first structure 180 may be disposed on the second structure 182. In some example embodiments, the first structure 180 may be the same or substantially the same as the structure of FIGS. 5 to 9 or the structure of FIGS. 10 to 12. For example, the first structure 180 of FIG. 13 may be an inverted form of the structure of FIG. 6 or the structure of FIG. 11. However, the first structure 180 may further include at least one first bonding pad 170 provided in a first interlayer insulating layer 138 closest to the second structure 182.

The second structure 182 may include a second substrate 202, gates 204 on the second substrate 202, second contact plugs 206, second wirings 208, second interlayer insulating layers 210, and a second bonding pad 172. The second substrate 202 may be a semiconductor substrate. An element isolation pattern may be provided in the second substrate 202 to define active regions. Each of the gates 204 may be disposed on a corresponding active region of the second substrate 202 with a gate dielectric layer interposed therebetween. Source/drain regions (not shown) may be provided in the corresponding active regions at both sides of each of the gates 204.

The second interlayer insulating layers 210 may be provided on the second substrate 202 to cover the gates 204. The second wirings 208 and the second contact plugs 206 may be provided in the second interlayer insulating layers 210 and may route (e.g., interconnect) transistors including the gates 204. At least one second bonding pad 172 may be provided in an uppermost one of the second interlayer insulating layers 210.

A lowermost one of the first interlayer insulating layers 138 may be bonded to the uppermost one of the second interlayer insulating layers 210, and the first bonding pad 170 may be bonded to the second bonding pad 172. The first structure 180 may be electrically connected to the second structure 182 through the first and second bonding pads 170 and 172.

For example, the lowermost first interlayer insulating layer 138 and the uppermost second interlayer insulating layer 210 may be formed of silicon oxide, and the first and second bonding pads 170 and 172 may include copper. For example, the lowermost first interlayer insulating layer 138 and the uppermost second interlayer insulating layer 210 may be bonded to each other by an oxide-to-oxide bonding method, and the first and second bonding pads 170 and 172 may be bonded to each other by a copper-to-copper bonding method.

However, some example embodiments of the present disclosure are not limited to the above-described electrical connection method of the first and second structures 180 and 182. In some example embodiments, the first and second bonding pads 170 and 172 may be omitted, and the first structure 180 may be electrically connected to the second structure 182 through a through-electrode (not shown) passing through an edge region of the first structure 180. Alternatively, the first structure 180 may be electrically connected to the second structure 182 through the through-electrode (not shown) and the first and second bonding pads 170 and 172.

In some example embodiments of the present disclosure, the image sensor may further include a third structure (not shown) between the first structure 180 and the second structure 182. For example, the first structure 180 may not include the above-described logic transistors, and the third structure (not shown) may include the logic transistors. For example, the first and third structures may be electrically connected to each other through bonding pads each included in the first and third structures and bonded to each other, and the third and second structures may be electrically connected to each other through bonding pads each included in the third and second structures and bonded to each other.

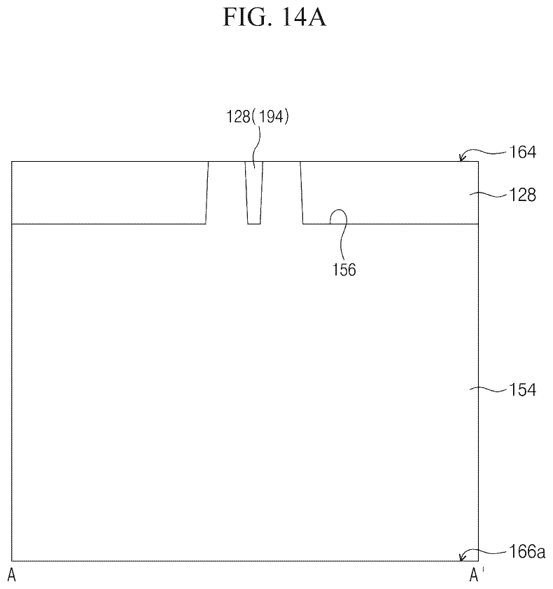

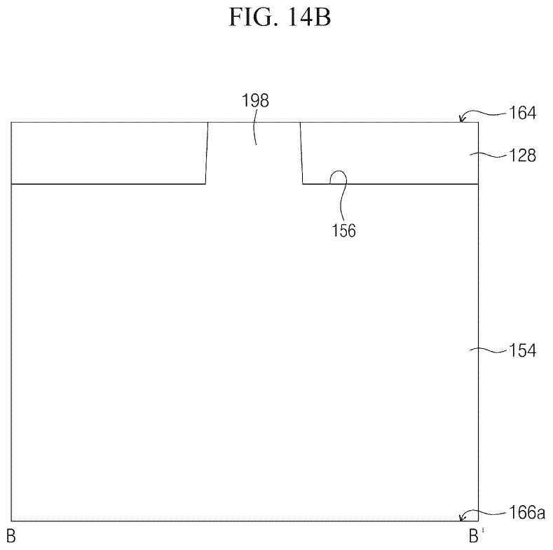

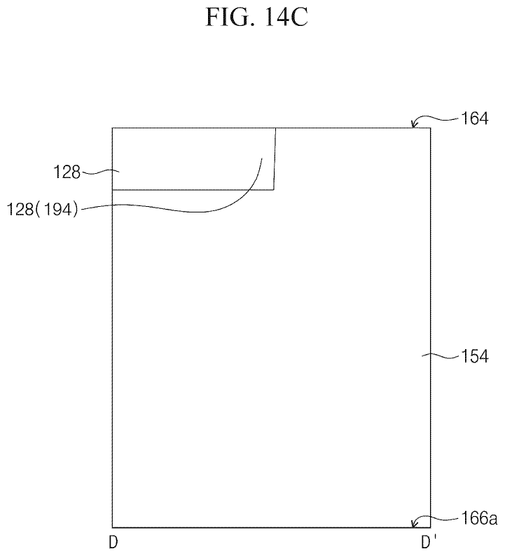

FIGS. 14A to 20A are for explaining a method of manufacturing the image sensor according to some example embodiments of the present disclosure, which are cross-sectional views corresponding to line A-A′ of FIG. 5. FIGS. 14B to 20B are for explaining the method of manufacturing the image sensor according to some example embodiments of the present disclosure, which are cross-sectional views corresponding to line B-B′ of FIG. 5. FIGS. 14C and 17C to 20C are for explaining the method of manufacturing the image sensor according to some example embodiments of the present disclosure, which are cross-sectional views corresponding to D-D′ of FIG. 5.

Referring to FIGS. 14A to 14C, the substrate 154 having the first surface 164 and a second surface 166a opposite to the first surface 164 may be prepared. The may be formed in the substrate 154 to define the first active regions 108 (see FIG. 5) and the second active regions 110 (see FIG. 5). Each of the first active regions 108 may include the channel portion 198. For example, the substrate 154 may be patterned to form the shallow trench 156, and the shallow isolation pattern 128 may be formed to fill the shallow trench 156. The shallow trench 156 may be recessed from the first surface 164 of the substrate 154. The shallow isolation pattern 128 filling the shallow trench 156 may be formed using at least one of a deposition process or an oxidation process.

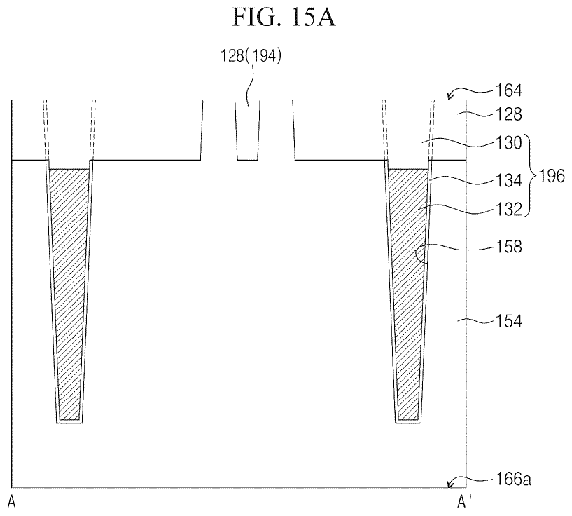

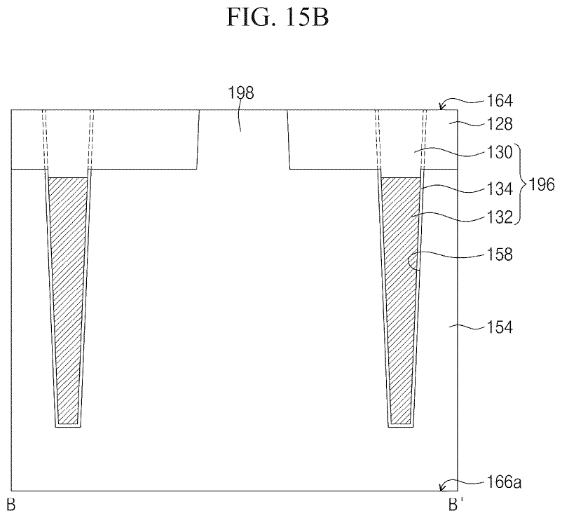

Referring to FIGS. 15A and 15B, the shallow isolation pattern 128 and the substrate 154 may be patterned to form the deep trench 158. The deep trench 158 may extend from the first surface 164 of the substrate toward the second surface 166a of the substrate 154. Bottom surfaces of the deep trench 158 may be spaced apart from the second surface 166a of the substrate 154. The deep trench 158 may pass through the shallow isolation pattern 128.

An insulating liner film may be conformally formed on the first surface 164 of the substrate 154 having the deep trench 158, and a buried conductive film may be formed on the insulating liner film to fill the deep trench 158. The insulating liner film may be formed using at least one of a deposition process or an oxidation process, and the buried conductive film may be formed using a deposition process. The buried conductive film may be etched to form the buried pattern 132 in the deep trench 158. An upper end of the buried pattern 132 may be lower than the first surface 164 of the substrate 154.

Subsequently, a capping insulating film may be formed on the first surface 164 of the substrate 154 to fill an upper region of the deep trench 158. A planarization process may be performed on the capping insulating film and the insulating liner film to form the insulating liner 134 and the capping insulating pattern 130 in the deep trench 158. The insulating liner 134, the capping insulating pattern 130, and the buried pattern 132 may constitute the deep PD isolation pattern 196.

The deep PD isolation pattern 196 may be formed in the substrate 154 to define the first to fourth photoelectric conversion element (PD) regions 100, 102, 104, and 106 (see FIG. 5). The first active region 108 and the second active region 110 may be defined in each of the first to fourth photoelectric conversion element (PD) regions 100, 102, 104, and 106.

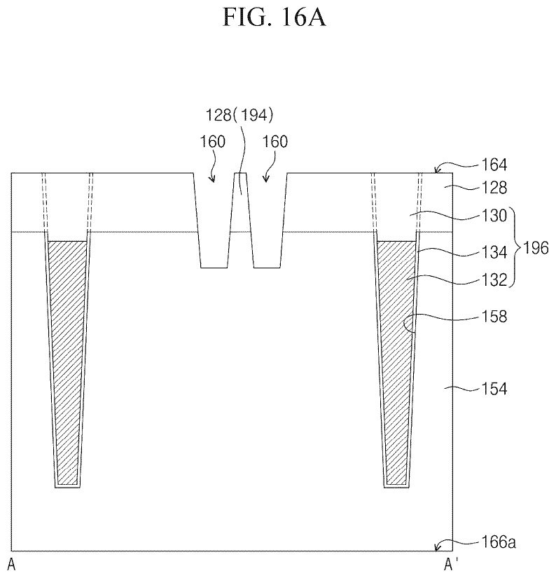

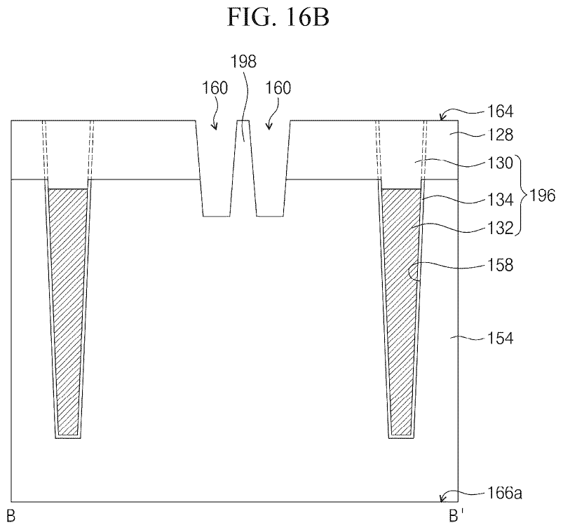

Referring to FIGS. 16A and 16B, the pair of gate trenches 160 may be formed in the first active region 108 of each of the first to fourth photoelectric conversion element (PD) regions 100, 102, 104, and 106. For example, a mask pattern (not shown) having openings defining the gate trenches 160 may be formed on the first surface 164 of the substrate 154, and the substrate 154 (e.g., the first active region 108) may be etched using the mask pattern (not shown) as an etch mask to form the gate trenches 160. The mask pattern (not shown) may be removed after forming the gate trenches 160.

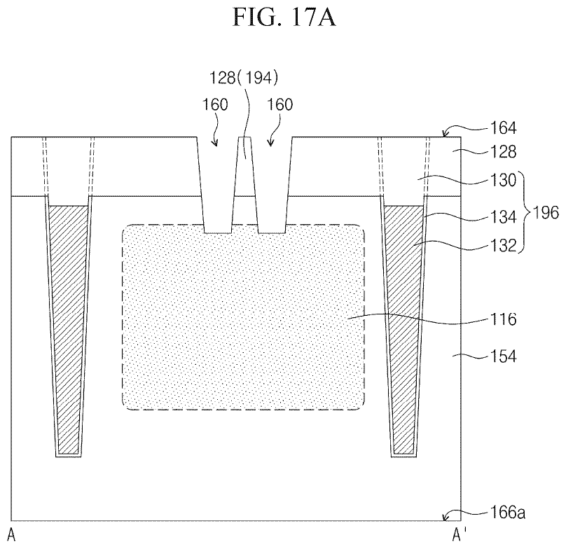

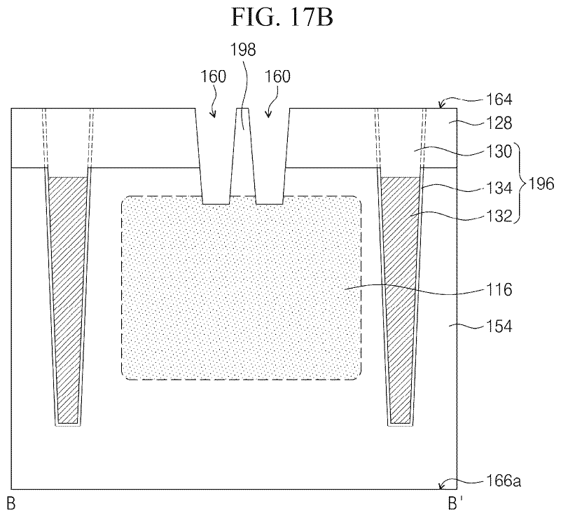

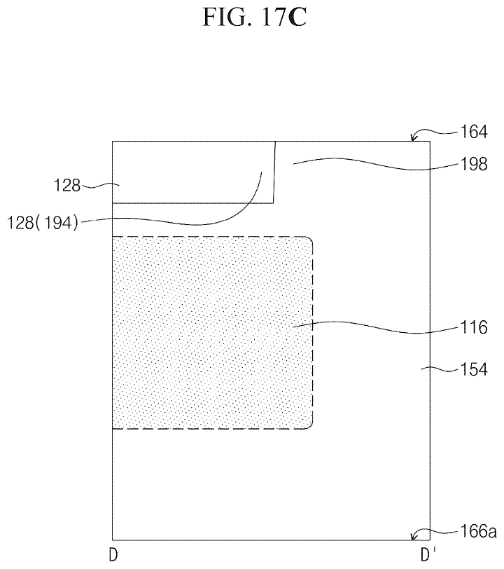

Referring to FIGS. 17A to 17C, impurities of the second conductivity type may be implanted into the substrate 154 to form the photoelectric conversion element (PD) 116 in each of the first to fourth photoelectric conversion element (PD) regions 100, 102, 104, and 106. Some example embodiments of the present disclosure are not limited to the above-described order of forming the photoelectric conversion element (PD) 116. In some example embodiments, the photoelectric conversion elements (PD) 116 may be formed before forming the shallow trench 156 or after forming the deep PD isolation pattern 196.

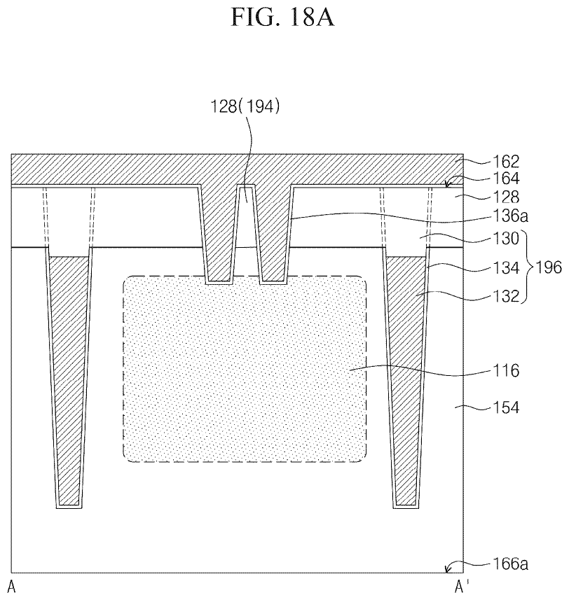

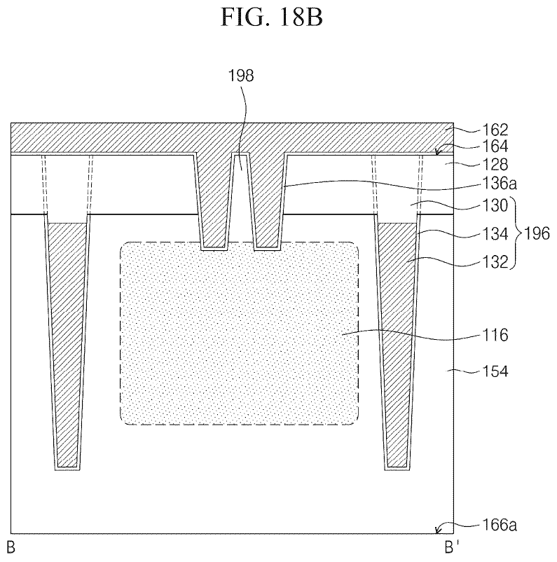

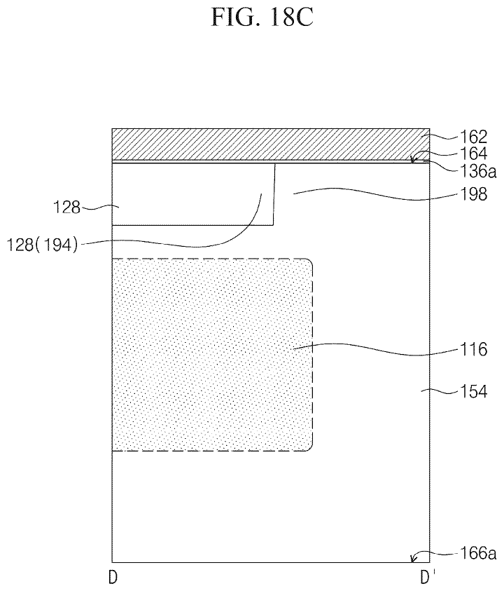

Referring to FIGS. 18A to 18C, a gate insulating film 136a may be formed on inner surfaces of the pair of gate trenches 160 and on the first surface 164 of the substrate 154. Subsequently, a gate conductive film 162 may be formed on the gate insulating film 136a. The gate conductive film 162 may fill the pair of gate trenches 160.

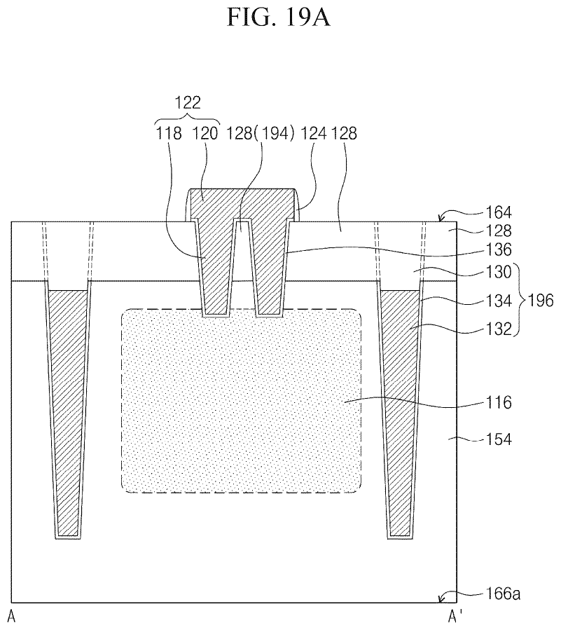

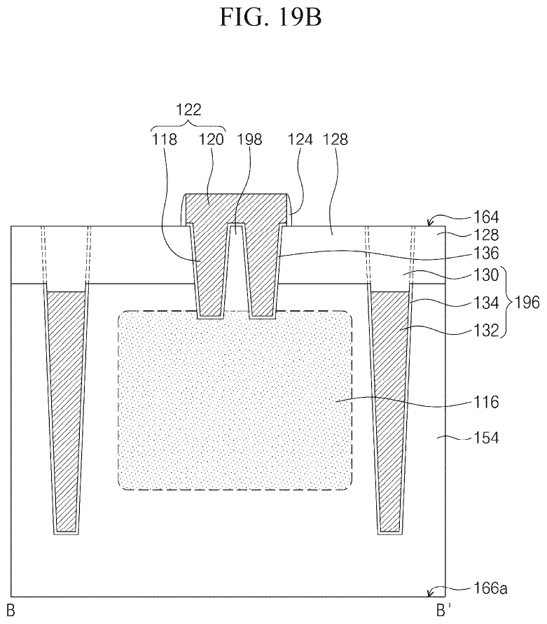

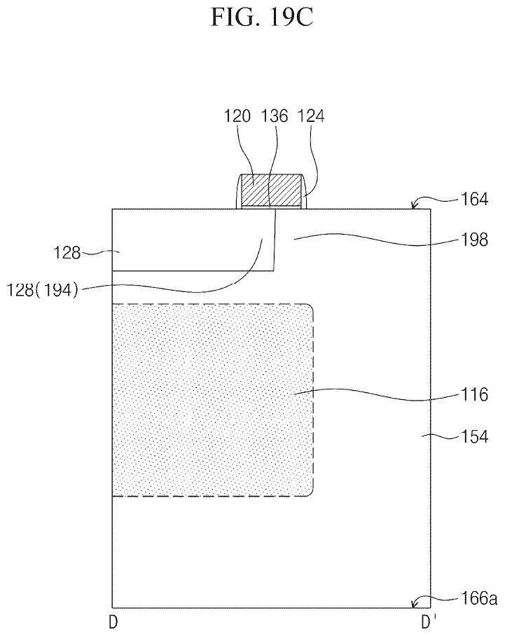

Referring to FIGS. 19A to 19C, the gate conductive film 162 may be patterned to form the transfer gates 122 and the gate electrodes 126 (see FIG. 5). The transfer transistor gate (TG) 122 may include the pair of vertical portions 118 and the horizontal portion 120 connected to the pair of vertical portions 118. The gate spacers 124 may be formed on side surfaces of each of the transfer transistor gate (TG) 122 and the gate electrode 126.

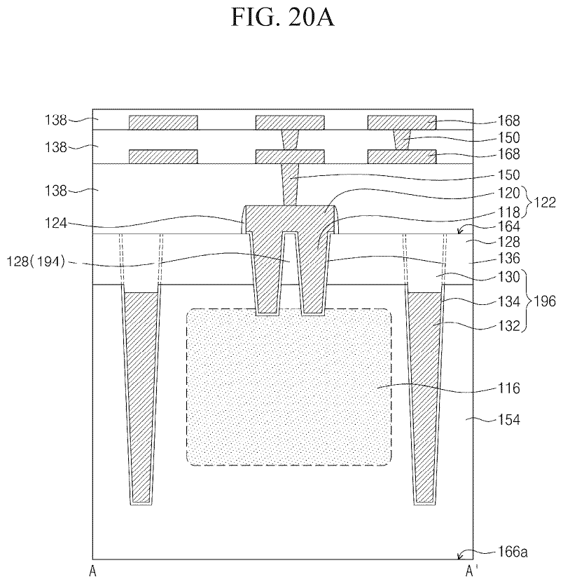

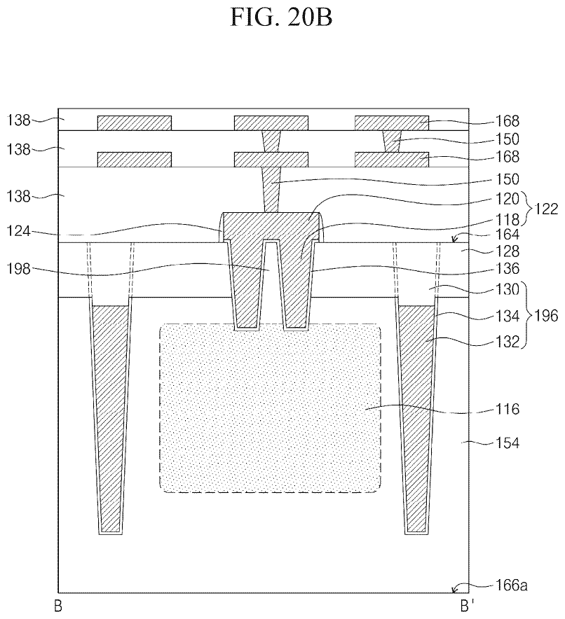

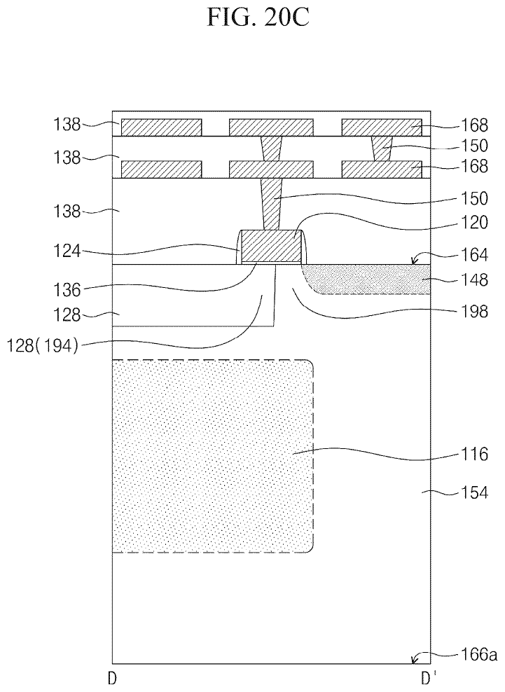

Referring to FIGS. 20A to 20C, impurities of the second conductivity type may be implanted into the first active region 108 at one side of the transfer transistor gate (TG) 122 to form the floating diffusion region 148. Source/drain regions (not shown) may be formed in the second active region 110 at both sides of the gate electrode 126. The source/drain regions (not shown) may be doped with the impurities of the second conductivity type. The source/drain regions (not shown) and the floating diffusion region 148 may be formed simultaneously.

Subsequently, the first interlayer insulating layers 138, the first wirings 168, and the first contact plugs 150 may be formed on the first surface 164 of the substrate 154. Thereafter, the substrate 154 may be turned over. The second surface 166a of the substrate 154 may be polished until the buried pattern 132 is exposed. For example, the polished second surface 166 of the substrate 154 may be coplanar or substantially coplanar with the exposed surface of the buried pattern 132. For example, the second surface 166a of the substrate 154 may be polished through a chemical mechanical polishing (CMP) process. A hydrogen/deuterium annealing process may be performed to heal defects (e.g., dangling bonds, etc.) of the polished second surface 166 of the substrate 154.

The light transmission layer 140 may be conformally formed on the second surface 166 of the substrate 154 (e.g., see FIG. 6). The grid structure 144 may be formed on the light transmission layer 140, and a color filter array including the color filters 142 may be formed on the second surface 166 of the substrate 154 having the grid structure 144. A microlens array including the microlenses 146 may be formed on the color filter array.

Thereafter, the substrate 154 may be turned over, and the image sensor of FIGS. 5 to 9 may be manufactured.

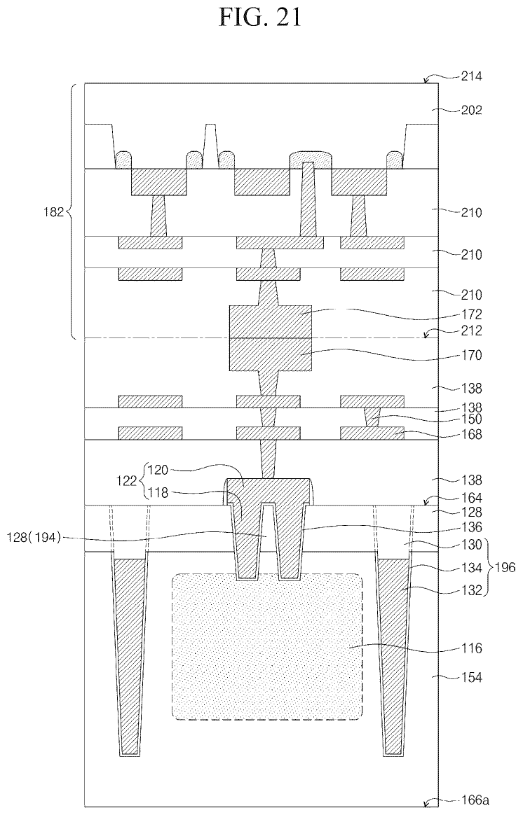

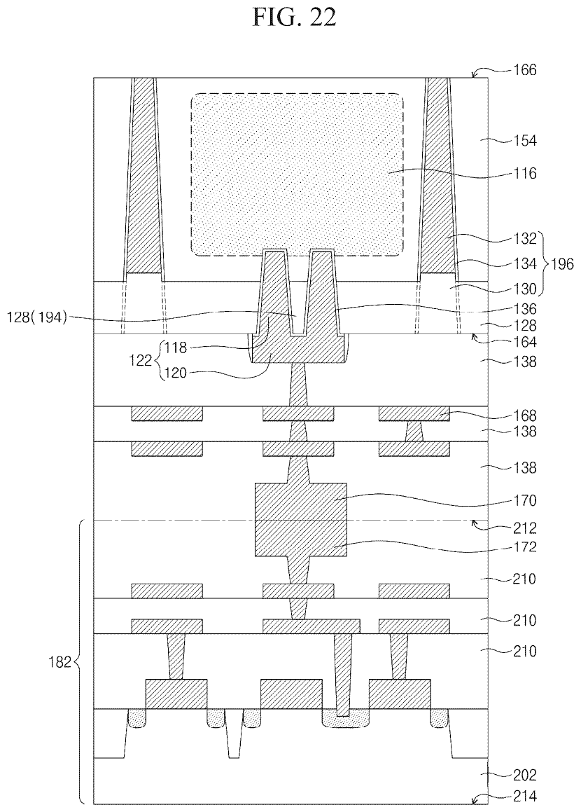

FIGS. 21 and 22 are cross-sectional views for explaining a method of manufacturing the image sensor according to some example embodiments of the present disclosure.

Referring to FIG. 21, the first bonding pad 170 may be formed in the uppermost one of the first interlayer insulating layers 138 of the structure of FIG. 20A. The second structure 182 having a third surface 212 and a fourth surface 214 may be prepared. The second structure 182 may include the same or substantially the same structure as the second structure 182 of FIG. 13. The third surface 212 of the second structure 182 may correspond to a lower surface of the lowermost second interlayer insulating layer 210, and the fourth surface 214 of the second structure 182 may correspond to a back surface of the second substrate 202.

The third surface 212 of the second structure 182 may be bonded to an upper surface of the uppermost first interlayer insulating layer 138 and an upper surface of the first bonding pad 170. For example, the lower surface of the lowermost second interlayer insulating layer 210 may be bonded to the upper surface of the uppermost first interlayer insulating layer 138, and a lower surface of the second bonding pad 172 may be bonded to the upper surface of the first bonding pad 170.

Referring to FIG. 22, subsequently, the bonded structure of FIG. 21 may be turned over. Thereafter, the second surface 166a of the substrate 154 may be polished to expose the buried pattern 132. Subsequently, the light transmission layer 140, the grid structure 144, the color filters 142, and the microlenses 146 may be formed on the polished second surface 166 of the substrate 154. Accordingly, the image sensor of FIG. 13 may be manufactured.

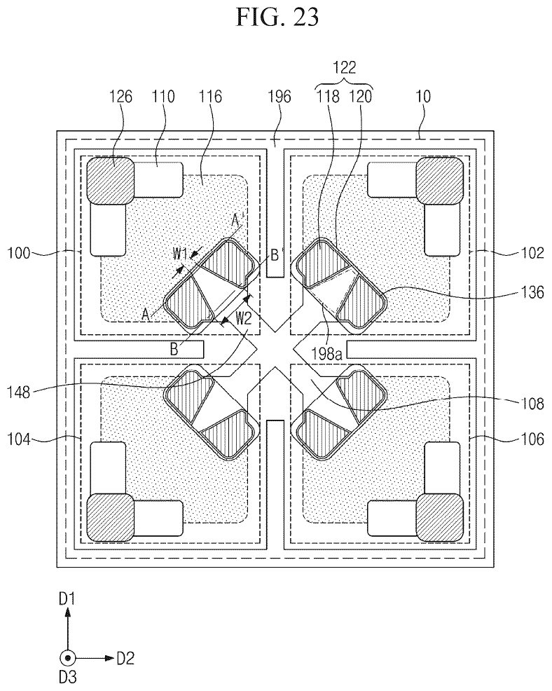

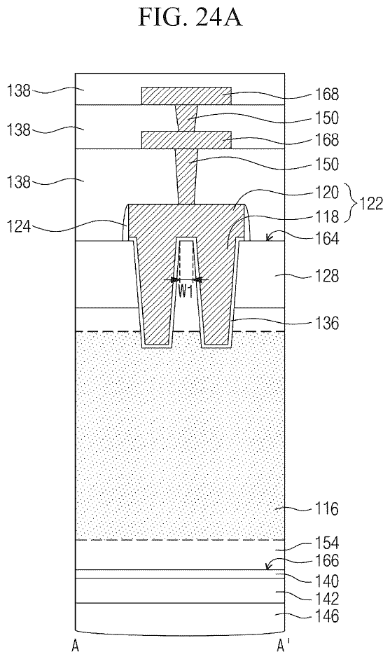

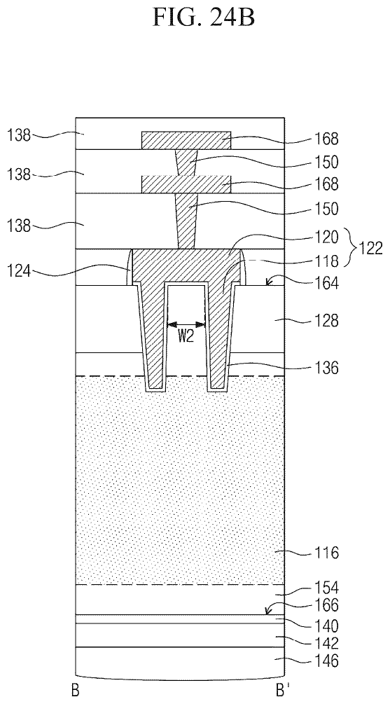

FIG. 23 is a plan view showing a pixel region group of an image sensor according to some example embodiments of the present disclosure. FIGS. 24A and 24B are cross-sectional views respectively taken along line A-A′ and line B-B′ of FIG. 23. The image sensor according to the present embodiment may be similar to the image sensor described above with reference to FIGS. 5 to 9. Therefore, hereinafter, for convenience of explanation, differences between the image sensor according to the present embodiment and the above-described image sensor will be mainly described.

Referring to FIGS. 23, 24A and 24B, the first active region 108 may include a channel portion 198a between the pair of vertical portions 118. The channel portion 198a may have a first end and a second end. The second end of the channel portion 198a may be adjacent to the floating diffusion region 148. The first end of the channel portion 198a may be opposite to the second end and adjacent to the shallow isolation pattern 128. A width W2 of the second end of the channel portion 198a may be larger than a width W1 of the first end of the channel portion 198a. For example, in a plan view, a width of the channel portion 198a may gradually increase toward the floating diffusion region 148. According to some example embodiments of the present disclosure, the amount of photocharges may be increased due to the second end of the channel portion 198a having a relatively large width. Accordingly, photocharge transfer efficiency can be improved.

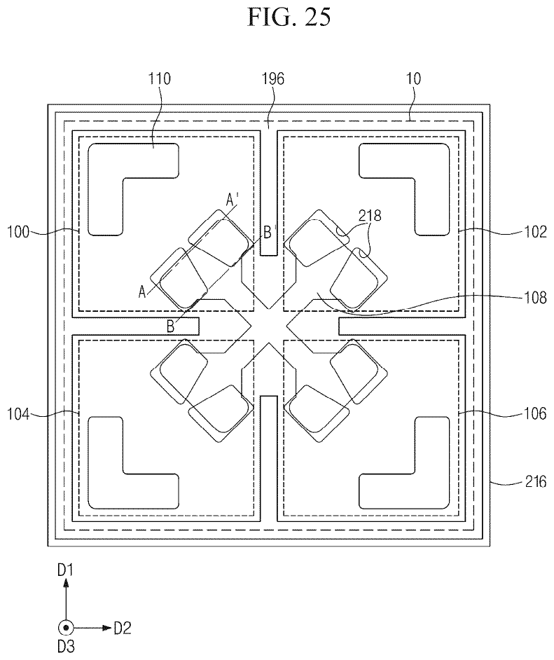

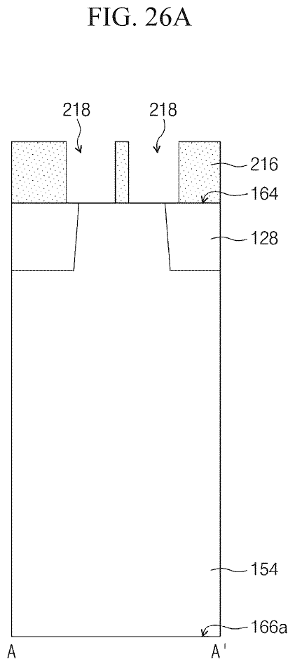

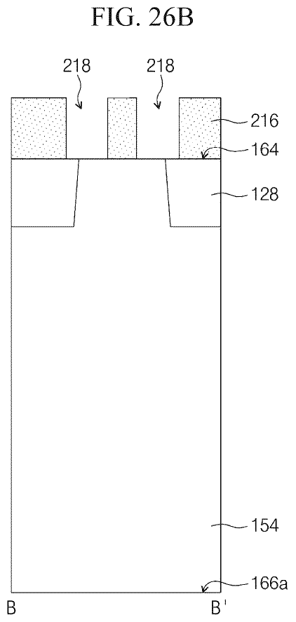

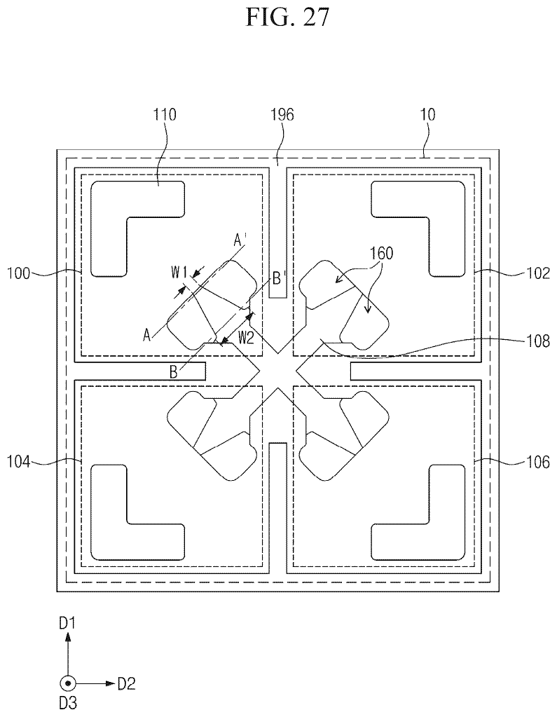

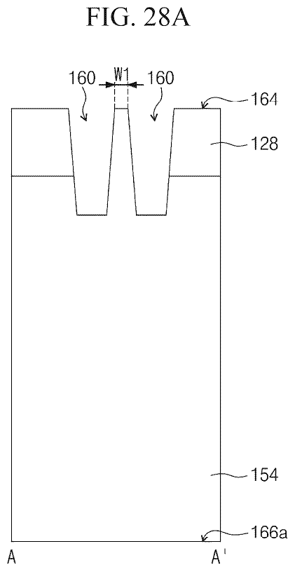

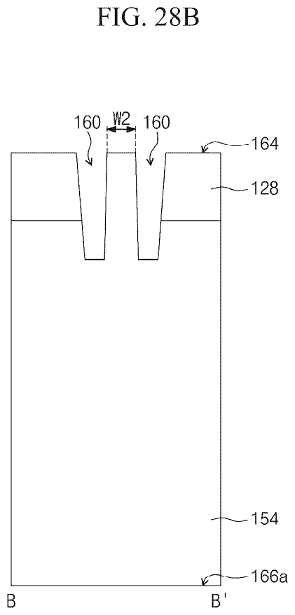

FIGS. 25 and 27 are plan views showing a method of manufacturing the image sensor according to some example embodiments of the present disclosure. FIGS. 26A, 26B, 28A and 28B are cross-sectional views taken along line A-A′ and line B-B′ of FIGS. 25 and 27, respectively.

Referring to FIGS. 25, 26A and 26B, a mask pattern 216 defining the gate trench 160 may be formed on the structure of FIG. 14A. The mask pattern 216 may be formed of a material having etch selectivity with respect to the substrate 154. For example, the mask pattern 216 may include a photoresist. The mask pattern 216 may have a pair of openings 218 corresponding to each of the first to fourth photoelectric conversion element (PD) regions 100, 102, 104, and 106. Each of the openings 218 may expose a portion of the first active region 108 and the shallow isolation pattern 128 adjacent thereto. In a plan view, the pair of openings 218 may be symmetrical with respect to each other, but some example embodiments of the present disclosure are not limited thereto. The pair of openings 218 may be disposed to define a shape of the channel portion 198a of FIG. 23 in the plan view.

An etching process may be performed on the substrate 154 using the mask pattern 216 as an etching mask. Accordingly, the pair of gate trenches 160 may be formed. In the etching process, the shallow isolation pattern 128 may have etch selectivity with respect to the first active region 108. For example, in the etching process, the shallow isolation pattern 128 may also function as an etching mask. The etching process may be anisotropic etching (e.g., a dry etching process).

Subsequent processes may be the same or substantially the same as the processes described with reference to FIGS. 17A to 20C.

According to some example embodiments of the present disclosure, the transfer gate on the active region may include the vertical portions each filling the pair of gate trenches formed in the active region. The shallow isolation pattern may include the extension extending between the pair of vertical portions. The extension of the shallow isolation pattern and the channel portion of the active region may be provided between the pair of vertical portions. A length of a travel path of photocharges between the photoelectric conversion element (PD) and the floating diffusion region may be reduced due to the extension of the shallow isolation pattern. As a result, photocharge transfer efficiency can be improved.

According to some example embodiments of the present disclosure, the active region may include the channel portion between the pair of vertical portions, the channel portion may have a first end and a second end, and a width of the second end of the channel portion may be greater than a width of the first end of the channel portion. An amount of photocharges may be increased due to the second end of the channel portion having a relatively large width. Accordingly, photocharge transfer efficiency can be improved.

One or more of the elements disclosed above in FIG. 1 for example may include or be implemented in processing circuitry such as hardware including logic circuits; a hardware/software combination such as a processor executing software; or a combination thereof. For example, the processing circuitry may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, an application-specific integrated circuit (ASIC), etc.

In a method of manufacturing an image sensor according to some example embodiments of the present disclosure, the method may include preparing a substrate having a first surface and a second surface opposite to the first surface, forming a shallow isolation pattern and a deep isolation pattern in the substrate, the deep isolation pattern defining photoelectric conversion element regions in the substrate, and the shallow isolation pattern defining an active region including a channel portion in each of the photoelectric conversion element regions, forming a transfer gate on the active region, the transfer gate including vertical portions each filling a pair of gate trenches formed in the active region, and forming a gate insulating layer between the transfer gate and the active region.

The shallow isolation pattern may include an extension extending between the pair of vertical portions, and the extension of the shallow isolation pattern and the channel portion of the active region may be between the pair of vertical portions.

In some example embodiments, the forming of the transfer gate and the forming of the gate insulating layer may include forming the pair of gate trenches in the active region, forming a gate insulating film on an upper surface of the active region and inner surfaces of the pair of gate trenches, forming a gate conductive film on the gate insulating film to fill the gate trenches, and patterning the gate conductive film to form the transfer gate including the pair of vertical portions and a horizontal portion connected to the pair of vertical portions.

In some example embodiments, both side surfaces of the extension of the shallow isolation pattern may each form portions of side surfaces of the pair of gate trenches.

In some example embodiments, each of the pair of vertical portions may include a first portion adjacent to the extended portion of the shallow isolation pattern and a second portion adjacent to the channel portion.

Upper portions of the second portions of the pair of vertical portions may be in contact with each other, and lower portions of the second portions of the pair of vertical portions may be spaced apart from each other.

The channel portion may be provided between the lower portions of the second portions of the pair of vertical portions, and a contact portion of the pair of vertical portions may be adjacent to one side surface of the extension of the shallow isolation pattern.

In some example embodiments, the method may further include forming a photoelectric conversion element in each of the photoelectric conversion element regions, forming a floating diffusion region in the active region at one side of the transfer gate, and sequentially forming a color filter array and a microlens array on the second surface of the substrate.

In a method of manufacturing an image sensor according to some example embodiments of the present disclosure, the method may include preparing a substrate having a first surface and a second surface opposite to the first surface, forming a shallow isolation pattern and a deep isolation pattern in the substrate, the deep isolation pattern defining photoelectric conversion element regions in the substrate, and the shallow isolation pattern defining an active region including a channel portion in each of the photoelectric conversion element regions, forming a transfer gate on the active region, the transfer gate including vertical portions each filling a pair of gate trenches formed in the active region, forming a gate insulating layer between the transfer gate and the active region, and forming a floating diffusion region in the active region at one side of the transfer gate.

The active region may include the channel portion between the pair of vertical portions. The channel portion may have a first end and a second end in a plan view, and a width of the second end of the channel portion may be larger than a width of the first end of the channel portion.

In some example embodiments, the second end of the channel portion may be adjacent to the floating diffusion region.

The first end of the channel portion may be opposite to the second end. The first end of the channel portion may be adjacent to the shallow isolation pattern.

In a plan view, a width of the channel portion may gradually increase toward the floating diffusion region.

In some example embodiments, the forming of the transfer gate and the forming of the gate insulating layer may include forming the pair of gate trenches in the active region, forming a gate insulating film on an upper surface of the active region and inner surfaces of the pair of gate trenches, forming a gate conductive film on the gate insulating film to fill the gate trenches, and patterning the gate conductive film to form the transfer gate including the pair of vertical portions and a horizontal portion connected to the pair of vertical portions.

In some example embodiments, the deep isolation pattern may be formed after forming the shallow isolation pattern.

In some example embodiments, the method may further include forming a photoelectric conversion element in each of the photoelectric conversion element regions, and sequentially forming a color filter array and a microlens array on the second surface of the substrate.
Some example embodiments of the present disclosure further provide a method of manufacturing an image sensor that includes forming a deep isolation pattern defining photoelectric conversion element regions in a first surface of a substrate; forming a shallow isolation pattern defining an active region in the substrate, the active region including a channel portion in each of the photoelectric conversion element regions; forming a pair of gate trenches in the active region; and forming a transfer gate on the active region, the transfer gate including a pair of vertical portions filling the pair of gate trenches, the forming the shallow isolation pattern includes forming an extension that extends between the pair of vertical portions, and the channel portion of the active region is formed between the pair of vertical portions.
In some example embodiments of the method of manufacturing the image sensor, the transfer gate is formed as including a horizontal portion connected to the pair of vertical portions, and the horizontal portion covers the extension of the shallow isolation pattern and the channel portion of the active region.
In some example embodiments of the method of manufacturing the image sensor, the extension of the shallow isolation pattern is formed as including side surfaces, and the side surfaces each are included as portions of side surfaces of the pair of gate trenches.
In some example embodiments of the method of manufacturing the image sensor, each of the pair of vertical portions are formed as including a first portion adjacent to the extension of the shallow isolation pattern and a second portion adjacent to the channel portion, upper portions of the second portion of the pair of vertical portions are formed in contact with each other, lower portions of the second portion of the pair of vertical portions are formed spaced apart from each other, the channel portion is formed between the lower portions of the second portion of the pair of vertical portions, and a contacted portion of the pair of vertical portions is formed adjacent to one side surface of the extension of the shallow isolation pattern.
In some example embodiments, the method of manufacturing the image sensor further includes forming a photoelectric conversion element in each of the photoelectric conversion element regions; and forming a floating diffusion region in the active region at one side of the transfer gate.
In some example embodiments of the method of manufacturing the image sensor, the photoelectric conversion element regions are formed adjacent to each other as a photoelectric conversion element region group, the active region in each of the photoelectric conversion element regions of the photoelectric conversion element region group are formed to extend and be connected to each other, and the floating diffusion region in the each of the photoelectric conversion element regions of the photoelectric conversion element region group are formed to extend and be connected to each other.
In some example embodiments, the method of manufacturing the image sensor further includes forming microlenses on a second surface of the substrate that is opposite the first surface of the substrate; and forming color filters between the second surface of the substrate and the microlenses.
In some example embodiments of the method of manufacturing the image sensor, the channel portion is formed as having a width that gradually increases as approaching toward the floating diffusion region.

The above-described contents are specific embodiments for implementing the present disclosure. Further to the above-described embodiments, the present disclosure will also include embodiments that can be simply designed around or easily changed. The present disclosure will also include technologies that can be implemented by being easily modified using some example embodiments. Therefore, the scope of the present disclosure should not be limited to the above-described some example embodiments, but should be determined not only by the appended claims but also by the equivalents of the claims of the present disclosure.

What is claimed is:

1. An image sensor comprising:
a substrate having a first surface and a second surface opposing the first surface;
a first photoelectric conversion element (PD) region comprising a first PD in the substrate;
a second PD region comprising a second PD in the substrate;
a deep isolation pattern between the first PD and the second PD;
a transfer gate in the first PD region and comprising a horizontal portion on the first surface of the substrate, a first vertical portion extending into the substrate, and a second vertical portion extending into the substrate; and
a shallow isolation pattern,
wherein the first vertical portion and the second vertical portion are connected to the horizontal portion, and
wherein the shallow isolation pattern vertically overlaps with the horizontal portion in a first direction perpendicular to the first surface of the substrate.

2. The image sensor of claim 1, wherein each of the first vertical portion and the second vertical portion comprises an upper surface and a lower surface opposing the upper surface,
wherein a distance from the lower surface of the first vertical portion to the lower surface of the second vertical portion in a second direction perpendicular to the first direction in a first vertical view is greater than a distance from the upper surface of the first vertical portion to the upper surface of the second vertical portion in the second direction in the first vertical view.

3. The image sensor of claim 2, wherein the first PD region further comprising:
a floating diffusion region,
wherein the first vertical portion is between the shallow isolation pattern and the floating diffusion region in a second vertical view different from the first vertical view.

4. The image sensor of claim 3, wherein a height of the floating diffusion region from the first surface of the substrate in the first direction in the second vertical view is less than a height of the shallow isolation pattern from the first surface of the substrate in the first direction in the second vertical view.

5. The image sensor of claim 4, wherein a height of the first vertical portion from the first surface of the substrate in the first direction in the second vertical view is different from the height of the shallow isolation pattern from the first surface of the substrate in the first direction in the second vertical view.

6. The image sensor of claim 5, wherein the height of the first vertical portion from the first surface of the substrate in the first direction in the second vertical view is smaller than the height of the shallow isolation pattern from the first surface of the substrate in the first direction in the second vertical view.

7. The image sensor of claim 5, wherein upper portions of the first vertical portion and the second vertical portion are in contact with each other.

8. The image sensor of claim 5, further comprising:
a third PD region comprising a third PD in the substrate; and
a fourth PD region comprising a fourth PD in the substrate,
wherein the first PD, the second PD, the third PD and the fourth PD are sequentially arranged in a clockwise direction, and
wherein the floating diffusion region is shared by the first PD, the second PD, the third PD and the fourth PD.

9. The image sensor of claim 8, wherein the floating diffusion region vertically overlaps with each of the first PD region, the second PD region, the third PD region and the fourth PD region in a plan view.

10. The image sensor of claim 8, wherein an area of the horizontal portion in a plan view is greater than a combined area of the first vertical portion and the second vertical portion in a plan view.

11. The image sensor of claim 8, wherein the first PD region and the second PD region are arranged in a third direction different from the second direction in a plan view,
wherein the first PD region and the fourth PD region are arranged in a fourth direction perpendicular to the third direction in the plan view, and
wherein the first vertical portion and the second vertical portion are arranged in the second direction in the plan view.

12. The image sensor of claim 8, wherein the deep isolation pattern is in contact with the first surface and the second surface of the substrate.

13. An image sensor comprising:
a substrate having a first surface and a second surface opposing the first surface;
a first photoelectric conversion element (PD) region comprising a first PD in the substrate;
a second PD region comprising a second PD in the substrate;
a deep isolation pattern between the first PD and the second PD;
a transfer gate in the first PD region and comprising a horizontal portion on the first surface of the substrate, a first vertical portion extending into the substrate, and a second vertical portion extending into the substrate; and
a shallow isolation pattern,
wherein the first vertical portion and the second vertical portion are connected to the horizontal portion,
wherein the shallow isolation pattern is between the first vertical portion and the second vertical portion in a plan view, and
wherein an area of the horizontal portion in the plan view is greater than a combined area of the first vertical portion and the second vertical portion in the plan view.

14. The image sensor of claim 13, wherein the shallow isolation pattern vertically overlaps with the horizontal portion in a first direction perpendicular to the first surface of the substrate in the plan view.

15. The image sensor of claim 14, wherein an area overlapping with the horizontal portion and the shallow isolation pattern in the first direction is more than 60% less than the area of the horizontal portion in the plan view.

16. The image sensor of claim 15, wherein a center of the horizontal portion in a first vertical view is offset from a center of a first vertical portion in the first vertical view.

17. The image sensor of claim 15, wherein the first PD region further comprising:
a floating diffusion region,
wherein the first vertical portion is between the shallow isolation pattern and the floating diffusion region in a first vertical view.

18. The image sensor of claim 17, wherein a height of the floating diffusion region from the first surface of the substrate in the first direction in the first vertical view is less than a height of the shallow isolation pattern from the first surface of the substrate in the first direction in the first vertical view.

19. An image sensor comprising:
a substrate having a first surface and a second surface opposing the first surface;
a first photoelectric conversion element (PD) region comprising a first PD in the substrate;
a second PD region comprising a second PD in the substrate;
a third PD region comprising a third PD in the substrate;
a fourth PD region comprising a fourth PD in the substrate; and
a floating diffusion region vertically overlapping with the first PD region, the second PD region, the third PD region and the fourth PD region in a plan view,
wherein each of the first PD region, the second PD region, the third PD region and the fourth PD region comprising
a transfer gate comprising a horizontal portion on the first surface of the substrate, a first vertical portion extending into the substrate, and a second vertical portion extending into the substrate; and
a shallow isolation pattern,
wherein the first vertical portion and the second vertical portion are connected to the horizontal portion,
wherein the shallow isolation pattern is between the first vertical portion and the second vertical portion in the plan view, and
wherein an area of the horizontal portion in the plan view is greater than a combined area of the first vertical portion and the second vertical portion in the plan view.

20. The image sensor of claim 19, wherein each of the first vertical portion and the second vertical portion comprises an upper surface and a lower surface opposing the upper surface, and
wherein a distance from the lower surface of the first vertical portion to the lower surface of the second vertical portion in a first direction perpendicular to the first surface of the substrate in a first vertical view is greater than a distance from the upper surface of the first vertical portion to the upper surface of the second vertical portion in the first direction in the first vertical view.
